(19) United States
(12) Patent Application Publication
(10) Pub. No.: US 2007/0164271 A1
(43) Pub. Date: Jul. 19, 2007

(54) Resonant nanostructures and methods of use

(76) Inventor: W. Bradley Wait JR., Corte Madera, CA (US)

Correspondence Address: GREENBERG TRAURIG, LLP, ONE INTERNATIONAL PLACE, 20th FL, ATTN: PATENT ADMINISTRATOR, BOSTON, MA, 02110, US

(21) Appl. No.: 11/585,638

(22) Filed: Oct. 24, 2006

Related U.S. Application Data
(60) Provisional application No. 60/729,223, filed on Oct. 24, 2005.
(60) Provisional application No. 60/780,886, filed on Mar. 10, 2006.

(51) Int. Cl. H01L 29/06

(52) U.S. Cl. 257/25

(57) ABSTRACT

Resonant nanostructures (RNSs) are provided in one embodiment of the present invention. RNSs may be nano- to micro-scale structures that resonate at specific frequencies through the application of an electromagnetic or acoustic stimulus. Resonant nanostructures provide new tools for diagnosing and treating disease. Resonant activation (RA) is also provided. RA may be a method of stimulating targeted chemical compounds, or nano- or micro-scale structures, in vivo and/or in vitro, to induce a response therefrom. Some RNSs include cavities that are configured to carry a payload. The resonant response of the target may include resonating, fracturing of the structure, and exposing or releasing of a payload. Targets may be changed or engage in various interactions as part of the resonant response. Such changes may include any of activating, triggering, de-activating, stimulating, attracting, repelling, joining, separating, assembling or disassembling of constituent components of a larger assembly, changing corformation, magnetizing, aligning, positoning, moving, or otherwise altering the target of the stimulus or stimuli.

### RELATED APPLICATIONS

This patent application claims priority to U.S. Provisional Patent Application Ser. Nos. 60/729,223, entitled Resonant Nanocrystals, filed on Oct. 24, 2005, and 601780,886, entitled Resonant Activation, filed on Mar. 10, 2006, both of which are hereby incorporated herein by reference.

### BACKGROUND OF THE INVENTION

Conventional medicines and therapeutic and diagnostic methods are effective for many disease conditions, but have a broad spectrum of limitations and unwanted effects. Most anti-cancer treatments, for example, are non-specific and can kill healthy cells, including those of the immune system. The treatment itself can be life threatening by making the patient susceptible to secondary infections. Similarly, ionizing radiation therapies are nonspecific and can damage healthy tissues to the detriment of the patient.

The application of a chemotherapeutic drug provides little control of the timing of when the drug affects the target cancer cells. The timing depends on many factors including the nature of the drug itself, its absorption and elimination profiles, and the metabolic health of the patient. Because of these factors and the complications of side-effects, chemotherapies must be carefully administered and monitored to achieve maximum benefit with minimum detrimental effects on the patient. Chemo-therapeutic cancer therapies have limited effect on CNS malignancies because they have difficulty crossing the blood/brain barrier given their size, weight, and the permeability of the barrier.

One of the most significant limitations for current cancer therapies involves imaging technology. It is that it is difficult to identify diseased tissue from healthy tissue. Most imaging is not effectively targeted to the diseased areas. Significant expertise is required by a radiologistto analyze the results of these images and identify potential diseased sites. Also, the resolution of current techniques and the signal-to-noise ratios of tissues make it difficult to image small lesions. In fact, early-stage cancers are virtually undetectable and must become as large as 1-mm (or a billion cells) before they can be detected by imaging techniques. Cancer patients who have been treated for the disease cannot be certain that the cancer has been completely eliminated. For fast growing and metastasizing cancers, this limited diagnostic ability means that initial treatment or follow-up treatment for recurrent disease is usually started too late for an effective outcome.

Existing medical imaging techniques used to diagnose, stage, and treat cancer, have limitations with respect to spatial resolution, temporal resolution, contrast, and artifacts. For example, most imaging scans only show innate density of scanned regions and contrast is limited. Dyes and other contrasting agents, radionuclides, and other chemicals can increase contrast and resolution to only a modest degree. There are also inherent risks to using contrast dye techniques, including allergic reactions and side effects. Radionuclides also have their inherent risks and require careful monitoring and control.

Certain anti-microbial therapies have limited targeting and specificity capabilites. They can adversely affect healthy tissues as well as the targeted microbial cells. For example, broad spectrum antibiotics can kill healthy and necessary bacterial flora within the host, thereby creating other health problems and unwanted side effects. In addition, certain anti-microbial therapies can cause allergic reactions in some patents, making them unusable, and in worst cases, life threatening. Antibiotics can also create drug resistant strains, this consequence limits the viability of the treatment and shortens the time the drug will be an effective anti-microbial agent. Current anti-microbial therapies cannot be temporally controlled or activated; once administered, they are put into play. Their effectiveness depends on many factors including the nature of the drug itself, its absorption profile, its elimination profile, and the metabolic health of the patent.

Conventional drug delivery for cancer and other diseases has limitations as well. Once a medicine or drug is administered, the timeline is activated and there is limited control of when and where drug is delivered. This timeline for delivery is pre-determined based on absorption rates, metabolic processes, and other processes. Concentration of delivered drug to desired tissues is also dependent on these processes. There is no way to confirm the drug has reached the desired target tissues and in what concentration it is. It is also not possible to confirm the involvement of non-target tissues by the drug.

Thus, cancer therapies, medical imaging technologies, and antibiotic therapies all would benefit from agents and methods of delivery that would improve control of specificity with regard to targeting of cells and timing of agent delivery.

### SUMMARY OF THE INVENTION

Embodiments of the invention include resonantnanostructures and methods of inducing a resonant response in responsive nanostructures. Resonant Nanocrystals are an example of a resonant nanostructure. Resonant nanostructures, in one embodiment, includes at least one nanoscaled structure measuring from about 1 nanometer to about 1000 nanometers in at least one dimension. Resonant nanostructures may also be capable of mounting a resonant response to an external stimulus, such as an electromagnetic or acoustic stimulus. The resonant response of the structure may occur in a time frame of between one picosecond to an hour or more, following such stimulation. The resonant response, in an embodiment, may be controlled by a time course of the stimulus, strength or magnitude of the stimulus, as well as aspects of local environment of the structure, and a resonant potential of the nanostructure.

Some resonant nanostructures may have cavities, and as such may be referred to as cavitated nanostructures, while others may be solid, at least to the extent that they may not have a substantial cavity. The cavity of a cavitated resonant nanostructure may include a payload; such may be a chemical compound, or another nanostructure, albeit smaller than a “host” nanostructure.

In response to a resonance elicited by stimulation, a resonant nanostructure may, in some cases, fracture, and in other cases, remain intact. Some resonant nanostructures capable of fracture may include, within their structure, specific faults or fracture points that represent a statistically dominant point of fracture. Such fracture points may be designed to be particularly fragile or vulnerable to specific types or force levels of stimulus.

Some resonant nanostructures include specific structural features that modulate resonance include harmonic structures that are particularly responsive to specific types or force levels of stimulus, and enhance or modulate or allow tuning of the resonant response of the structure as a whole.

Some resonant nanostructures are decorated or coated on their external surface with compounds configured to attract or bind them. Such interactions may be of any physicochemical form of interaction, including ionic interaction, hydrophilic/hydrophobic interactions, magnetic interaction, or ligand-receptor interaction. Further, the surface of some resonant nanostructures may include regions that are electrically charged, magnetically polarized, or include hydrophilic, hydrophobic, or amphiphatic regions. As mediated by such physicochemical features, the resonant nanostructural interaction with other entities may include the attraction, or in some cases, repulsion, of small or large molecules, whole cells, based on the nature of their surface features, or other nanoscale structures or devices.

In some resonant nanostructures, the surface may include a coating that protects the nanostructure from environmental insult, and may thereby protect the nanostructure as a whole, or specific vulnerable internal structures, or the contents of the nanostructure. In some cases, a coating may be configured so as to resonate, itself, or enhance or modulate the resonant responsiveness or fracturability of the nanostructure as a whole to electromagnetic or acoustic stimulation

In some resonant nanostructures configured to interact with biological cells, interaction may include attachment to the cell surface, or it may further include lysing or the cell membrane, or internalization by the cell, through any of the normal cellular pathways, such as receptor mediated internalization. Once internal within the cell, resonant nanostructures may be handled by normal cellular mechanisms, or the nanostructures may be more active in terms of their own fate, as a function of their surface features or payload. The effects on cells may be negative, as for example killing the cell, or initiating apoptosis, or it may allow interactions that provide for diagnostic methods that identify specific types of cells or identify physical or chemical features within cells.

In resonant nanostructures that carry a payload in a cavity, the fracturing of such the nanostructure may provide for the exposure, release, or expulsion of the payload. In some cases, the payload may include compounds in an “inactive” form, as for example an inactive toxin or inactive enzyme. In such cases, the resonant response may include the initiation of a process that culminates in the activation or the inactive payload.

Some resonant nanostructures may be configured to trap a chemical compound, a structure of nano-dimension, or a cellular organelle, once internalized within a cell. Some resonant nanostructures configured to attract molecules through the surface features or characteristics of the nanostructure, may be further configured to facilitate the assembly of macromolecules from component molecules.

Some resonant nanostructures that engage in interaction with compounds in their local environment through ionic, hydrophilic/hydrophobic, electrical, or magnetic interaction, may be configured to disassemble large compounds into components, or to effect separation or sequestering of specific compounds from a heterogeneous mixture.

As provided by aspects of the invention, inducing a resonant response in a resonatable target nanostructure may occur by way of electromagnetic or acoustic stimulation. The resonatable target may include a nanoscale structure or a device, or a structure of any atomic or molecular scale. Electromagnetic forms of stimulus may include one of microwaves, infrared, magnetic resonance imaging, nuclear magnetic resonance, computed tomography, electron beam tomography, single photon emission computed tomography, positron emission tomography, X-Rays, T-ray (TeraHertz) phonon imaging, or a combination thereof. Acoustic stimuli may include ultrasound or infrasound.

In some embodiments, a primary resonant target, upon stimulation and resonance, activates a second target (FIG. 17, Cascading resonant activation). In such cases, a resonant response may be amplified, or may be considered catalytic, in that the primary target may return to a quiet state, and be reused, and further amplified. Such secondary targets may be subject to all the variables and interactions described with regard to the primary target.

In some cases, a resonant target may be located in or on a biological system, including any form of animal, microbial or plant life. In some cases the resonant target located in a biological entity, may be stimulated by a source external to the entity, in which case the stimulus traverses through live tissue. In some cases, in response to the stimulus, the target, a resonant nanostructure, may be altered in ways described above.

In general terms, a resonant stimulus can occur on a time course, and can have a predetermined strength, as governed by the stimulating means. The stimulus may further be controlled or varied over a time course. In addition, local environment of the target may have an effect on delivery of the stimulus, as well as a response of a target to the stimulus. In an embodiment, the environment of the stimulating mechanism itself, especially if in a biological system, may have an effect on the stimulus. Accordingly, the resonant response may be influenced or controlled by these various factors. The resonant response may also include parameters such as a timeline, may include a lag phase, may range in duration from a picosecond to an hour or more, may include a spatial scope, and may include a magnitude. The parameters of the response may further be influenced by factors inherent in the nanostructure itself, the summation of which may be referred as the resonant potential of the target.

Resonant activation of resonant-enabled structures has many biomedical applications. The resonant response may be applied to medical imaging, the quality of the imaging (sensitivity and specificity) thereby improved with respect to any of the signal to noise ratio, spatial resolution, temporal resolution, contrast, or reduction of artifacts. It may further be applied to diagnostic, staging, or treatment of disease, such as cancer and neurological disease, among others. It may be applied to elucidate biological function at any of a system level, organ level, tissue level, cellular level, or intracellular level. The resonant response may be applied to real time confirmation of the occurrence of the resonant response. It may be further applied to real time confirmation of the occurrence of a consequence that follows from the resonant response. It may be still further applied to creating a biological response that can be measured in real time. In some embodiments, particularly those that engage in attraction, assembly or disassembly of molecular components, biomedical applications may include surgical aspects, as exemplified by wound closure or incision expansion and closure.

### BRIEF DESCRIPTION OF THE DRAWINGS

FIG. 1 shows various resonant nanostructures (RNSs), such as resonant nanocrystal (RNC) for use in connection with the present invention.

FIG. 2 shows RNSs of the present invention with a payload.

FIG. 3 shows RNSs nested within a cavity of other RNSs, in accordance with an embodiment of the present invention.

FIG. 4 shows RNSs with harmonic bridges to enhance and/or tune resonating responses of the RNS.

FIG. 5 shows RNSs with fracture regions to permit fracturing with a predictable fragment size and shape.

FIG. 6 shows RNSs having magnetically-polarized regions which can operate as magnetic monopoles or dipoles.

FIG. 7 shows RNSs having electrically-charged properties, as well as hydrophobic and hydrophilic properties to assist in delivery to target tissues.

FIG. 8 shows RNSs exposing and releasing a payload in accordance with an embodiment of the present invention.

FIG. 9 shows RNSs with a metabolic and/or functional coating to enable or enhance targeting, attachment or incorporation within cells.

FIG. 10 shows payload-coated RNSs activated by resonant activation or other means.

FIG. 11 shows RNSs having a resonant shell coating to protect a payload coating.

FIG. 12 shows RNSs with attached targeting molecule(s) to enhance targeting, attachment and/or incorporation within cells.

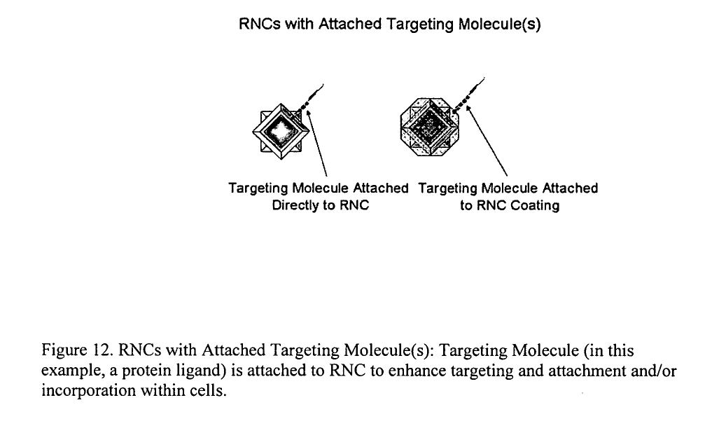

FIG. 13 shows RNSs having a molecular hinge (e.g. nano-traps) that allows them to have an open or closed configuration to attract or capture inter- and intra-cellular contents.

FIG. 14 shows resonant activation to induce a resonant response from RNSs.

FIG. 15 shows a resonant activation response from RNSs that can be recorded.

FIG. 16 shows cascading resonant activation which can induce a cascading response from RNSs.

FIG. 17 shows a fracturing response by RNSs which can result in fragmentation or simple cleaving of RNSs.

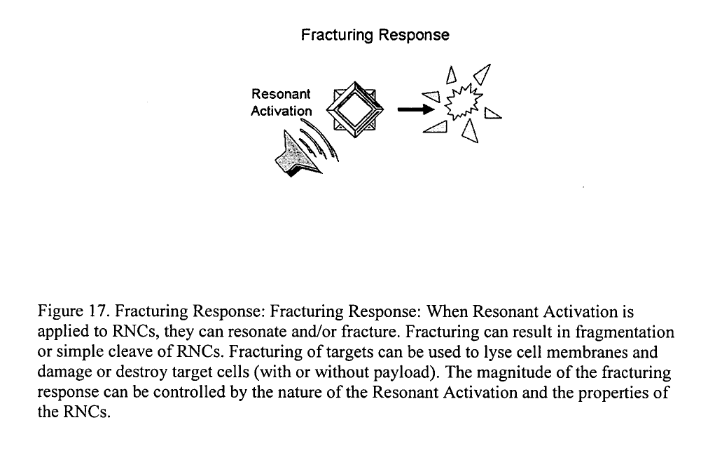

FIG. 18 shows exposing and releasing responses by RNSs when fractured to expose and/or release a payload.

FIG. 19 shows a fracturing response by nested RNSs which can enable n-tiered delivery of payloads.

FIG. 20 shows activating/triggering response of payload coating by resonant activation which can change conformation of a payload.

FIG. 21 shows activating/triggering response of payload by resonant activation which can change conformation of a payload.

FIG. 22 shows fracturing response of a resonant shell to expose and/or release a payload coating.

FIG. 23 shows a transformation response to a resonant activation to transform or change the conformation of an RNC.

FIG. 24 shows an alignment response to resonant activation to induce magnetic alignment of magnetic RNSs.

FIG. 25 shows an attracting response to resonant activation to induce magnetic attraction (magnetic convergence) to bring together magnetic RNSs.

FIG. 26 shows a separation response to resonant activation to induce magnetic repulsion (or divergence) to separate magnetic RNSs.

FIG. 27 shows a magnetic induction to resonant activation to induce magnetic alignment of magnetic RNSs.

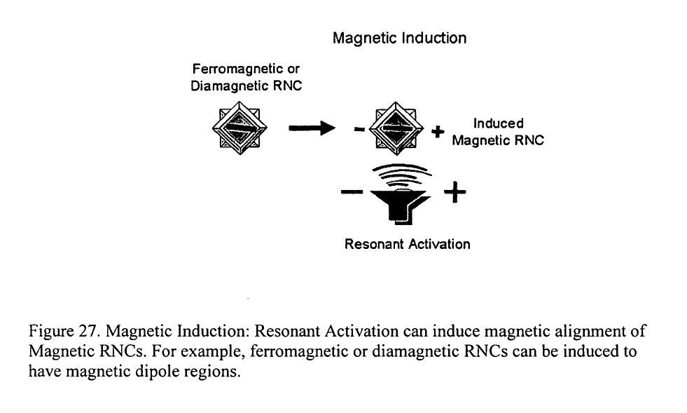

FIG. 28 shows an assembling response between magnetic RNSs to permit alignment and enable assembly of macromolecules and/or devices or structures.

FIG. 29 shows RNSs lysing cells to destroy a variety of targeted cells through the lysing of cell membranes.

FIG. 30 shows RNSs delivering a payload within a host including within cells, in the intercellular space, in lymphatic system, in circulatory system.

FIG. 31 shows the use of RNSs with neurons to improve neural function and/or improve resolution by imaging applications.

FIG. 32 shows RNSs as molecular probes or biomarkers for molecular imaging.

FIG. 33 shows RNSs as a nano-cage for time-release of a payload.

### DETAILED DESCRIPTION OF SPECIFIC EMBODIMENTS

Definitions

As used herein, the following terms may denote the following:

Activation Response: The response of a resonant nanostructure to resonant activation resulting in the resonant nanostructure changing from an inactive state or form to an active one and/or triggering another response. For example, an inactive chemical compound can activate by revealing/exposing an active site for binding with other chemical compounds, device or structure, tissues, and so on. For example, a device or structure can activate by switching from an off state to an on state, or becoming operationally active based on its intended design

Active Payload: Any payload that is operationally, functionally, or otherwise enabled to perform its intended action (See Payload).

Aligning Response: The response of a resonant nanostructure to resonant activation resulting in the resonant nanostructure aligning with other resonant nanostructures along a spatial plane.

Assembling Response (See Attraction Response)

Attraction Response: The response of a resonant nanostructure to resonant activation resulting in the resonant nanostructure attracting or joining to other resonant nanostructures, chemical compounds, or cell organelles. This attraction can include, but is not limited to, magnetic attraction, ionic attraction, atomic force attraction, hydrophilic/hydrophobic forces, among others

Cascading Response: A chain-reaction or catalytic process in which the resonant response of a resonant nanostructure initiates a resonant response in other resonant nanostructures or atoms or molecules.

Cavity RNC: A crystalline resonant nanostructure that has an internal cavity. The cavity can be empty or have attached or loose payload within. The cavity can be closed or open, and can function as a closed container, a cage (See Nano-Cage), or a combination that transforms from a closed to an open state and back again (See Nano-Trap). Cavity RNCs can resonate based on the physics of cavity resonance and other processes.

Changing Response (See Transformation Response)

Cleaving Response (See Fracturing Response)

Complex Fragmentation: The fracturing of a resonant nanostructure into more than two fragments (See Simple Cleave).

Conformation Response (See Transformation Response)

Conjoining Response (See Attraction Response)

Converging Response (See Attraction Response)

De-activation Response: The response of a resonant nanostructure to resonant activation resulting in the resonant nanostructure changing from an active state or form to an inactive one. For example, an active chemical compound can de-activate by hiding an active site for binding with other chemical compounds, device or structure, tissues, and so on. For example, a device or structure can de-activate by switching from an on-state to an off-state, or becoming operationally inactive, based on its intended design.

De-energizing Response: The response of a resonant nanostructure to resonant activation resulting in the resonant nanostructure becoming de-energized, de-excited, or de-stimulated to a lower potential energy state, thereby reducing their ability to release energy.

De-excitation Response (See De-energizing Response)

De-stimulation Response (See De-energizing Response)

Disassembling Response (See Separation Response)

Diverging Response (See Separation Response)

Energizing Response: The response of a resonant nanostructure to resonant activation resulting in the resonant nanostructure becoming energized, excited, or stimulated to a higher potential energy state, thereby enabling the structure to release energy in the form of heat, emit electrical energy, emit light, and/or vibrate, among others.

Excitation Response (See Energizing Response)

Exposing Response: The response of a resonant nanostructure to resonant activation resulting in the resonant nanostructure exposing its components and/or contents to the containing environment. For example, targets that carry fixed payloads can expose these payloads upon fracturing or cleaving.

Expulsion Response (See Releasing Response)

Fracturing Response: The response of a resonant nanostructure to resonant activation resulting in the resonant nanostructure fracturing into two or more fragments. The magnitude/strength of the fracturing response on a target chemical compound and/or device or structure can be controlled by one or more means, including the temporal or spatial activation of the applied external stimulus, the innate properties of the environment where the targets reside, and/or the innate properties of the target chemical compound and/or device.

Functional Attractant: Any substance that can attract resonant nanostructure to a cell because of its functional use or association with the cell. Functional attractants are agents that attract the resonant nanostructures to the target cells because of they provide functional benefit to the cells. These agents may include proteins, amino acids, ATP, GTP, nucleic acids, and so on.

Harmonic Bridge: A molecular structure attached to or within a resonant nanostructure that enhances and/or tunes its resonant frequencies.

Inactive Payload: Any payload that is operationally, functionally, or otherwise disabled from performing its intended action (See Payload).

Internal Payload: A payload located within a resonant nanostructure (loose, attached, or embedded).

Joining Response (See Attraction Response)

Magnetic Convergence: The attraction of magnetic resonant nanostructures to other magnetic resonant nanostructures.

Magnetic Divergence: The repulsion of magnetic resonant nanostructures from other magnetic resonant nanostructures.

Magnetizing Response: The response of a resonant nanostructure to resonant activation resulting in the resonant nanostructure becoming magnetized and thereby responding to magnetic forces.

Magnitude Response: The magnitude or strength of the response from a target chemical compound and/or device or structure can be controlled by one or more means, including but not limited to the temporal and spatial activation of the applied external stimulus or stimuli, the innate properties of the environment where the targets reside, and/or the innate properties of the target chemical compound and/or device.

Merging Response (See Attraction Response)

Metabolic Attractant: Any substance that can attract resonant nanostructure to a cell because of its metabolic use or association with the cell. Metabolic attractants are agents or comprise agents that attract the resonant nanostructures to the target cells because of the cell metabolic processes. These agents may include sugars, glycans/glycoproteins, vitamins such as folate, biotin, etc.

Molecular Hinge: A hinge-like molecules within a resonant nanostructure that enables it to function as a Nano-trap. The hinge enables the trap to be opened and closed in response to resonant activation (See Nano-Trap)

Moving Response (See Positoning Response)

Nano-Cage: A cavity resonant nanocrystal designed as a cage. Each cage can have one or more holes and can contain a payload. The payload can move out of the holes. This enables a timed-release of the payload based on the diffusion properties of the payload, the size and conformation of the cage holes relative to the payload, and other properties. Stimulating the resonant nanostructure through resonant activation can increase the speed of the release of the payload. Alternatively, the resonant nanocrystal can contain fracture regions that open up holes in the cage when resonant activation is applied.

Nano-lnjection: The process in which a resonant nanostructure attaches to a cell membrane and delvers a payload within a cell. This process is analogous to the way viruses deliver nuclear material intro cells.

Nano-Trap: A cavity resonant nanostructure (such as a resonant nanocrystal) that transforms from a closed to an open state and back again in response to resonant activation (See Transformation response).

Nano-Vector: See Nano-injection.

Nested RNC: A cavity resonant nanocrystal that contains one or more other resonant nanocrystal. Nested RNCs can enable N-tiered payload delivery (See N-tiered Response)

Neural Enhancement: The process of enhancing the function of neurons through by resonant nanostructures. For example, detection and response of sensory neurons to external stimuli (such as but not limited to auditory stimuli) can be improved by integration of or association with resonant nanostructures.

Non-Cavity RNC: A crystalline resonant nanostructure that has no internal cavity or one of insignificant size. Non-cavity RNCs can have an embedded payload. Non-cavity RNCs can resonate and be fractured in response to resonant activation.

N-tiered Response: The response of nested RNCs to resonant activation that results in a multi-stage delivery of payloads. A first tier of RNCs is fragmented to release its payload including nested RNCs. The nested RNCs are subsequently fractured to deliver a second tier release of payload.

Payload Activation: The process by which a payload becomes activated, usually in response to resonant activation (See Active Payload).

Payload Coating: An external coating of a resonant nanostructure that is comprised in some measure of a payload (see Payload).

Payload: Contents delivered to the host environment by a resonant nanostructure consisting of molecular, atomic, biological (viruses, bacteria, and so on), device, or nanoscaled structures, among others. The payload can be embedded within the resonant nanostructure, attached to a cavity wall, or loose within a cavity. Payloads can also attach to or coat the outside of the resonant nanostructure. Payloads can be active or inactive.

Positioning Response: The response of a resonant nanostructure to resonant activation resulting in the resonant nanostructure moving to a specific position. For example, structures can be positioned to a specific target tissue and/or region of the host.

Releasing Response: The response of a resonant nanostructure to resonant activation resulting in the resonant nanostructure releasing structures and/or contents to the containing environment. For example, targets that carry loose payloads can release these payloads upon fracturing or cleaving.

Repulsion Response (See Separation Response)

Resonant Activation (RA): Resonant activation is a method of applying a stimulus or stimuli to targets that include, but are not limited to sub-atomic particles/waves, atoms, molecules, chemical compounds, and/or nano- or micro-scale devices, in vivo and/or in vitro to induce, elicit, or affect a response from the targets. The response of the targets may include resonating, fracturing or cleaving, exposing, releasing, activating or triggering, de-activating, energizing, exciting, stimulating, de-energizing, de-exciting, de-stimulating, attracting or joining, separating or disassembling, transforming or changing conformation, magnetizing, aligning, positoning or moving, or otherwise changing or altering the target of the stimulus or stimuli. The nature of the applied stimulus or stimuli may include electromagnetic and/or acoustic forces, such as any of ultrasound, infrasound, microwaves, infrared, magnetic resonance imaging, nuclear magnetic resonance, computed tomography, electron beam tomography, single photon emission computed tomography, positron emission tomography, X-Rays, T-ray (TeraHertz) phonon imaging, as well as others.

Resonant Nanocrystals (RNCs): Resonant nanocrystals are resonant nanostructures wherein the composition resonant nanoscaled structure is crystalline. The crystal lattice of a resonant nanocrystal defines its basic internal and external physical structure. This lattice can be composed of elements, such as silicon, carbon, and others. Additional elements and/or molecules can be attached to the lattice, both externally and internally. RNCs include solid forms and cavitated forms; solid forms are termed Non-Cavity RNCs, and those with internal cavities (see Cavity RNCs). The cavities can either be empty or they may include a payload therein. RNCs can be designed with molecular structures that function as harmonic bridges to facilitate and/or tune the RNC resonance.

Resonant Nanostructures (RNSs): Resonant nanostructures comprise at least one nanoscaled structure, such as a vesicle or a particle, measuring from about 1 to about 1000 nanometers in at least one dimension. The nanoscaled structure has resonant properties and is capable of generating a resonant response to an external stimulus. For the following discussion, reference to the term “structure” can include one of nanoscaled structure, nanoscaled vesicle, nanoscaled particle, resonant nanostructure, RNSs, or any combination thereof.

Resonant Potential: The totality of the ability of an RNS to resonate influenced by factors inherent in the nanostructure itself.

Resonant Response Wave: The resonant wave or other signal generated by a resonant nanostructure in response to resonant activation.

Resonant Response: The response of a resonant nanostructure to resonant activation.

Resonant Shell: An outer coating on a resonant nanostructure that can be activated and/or fractured by resonant activation.

Resonant Signature: A response of a resonant nanostructure to resonant activation that can uniquely identify the target resonant nanostructure.

Resonating Response: The response of a resonant nanostructure to resonant activation resulting in the resonant nanostructure resonating and possibly emitting electromagnetic, mechanical, and/or acoustic energy.

Separation Response: The response of a resonant nanostructure to resonant activation resulting in the resonant nanostructure separating or dissassembling. This separation can include, but is not limited to, magnetic repulsion, ionic repulsion, atomic force repulsion, hydrophilic/hydrophobic forces, among others.

Silver Bullet: A resonant nanostructure containing a payload comprised of elemental silver atoms or a silver-containing compound.

Simple Cleave: The fracturing of a resonant nanostructure into two fragments (See Complex Fragmentation).

Spatial Activation: See Spatial Response.

Spatial Response: The spatial location or scope of the response from a target chemical compound and/or device or structure can be controlled by one or more means, including, for example, the position, proximity, angle, strength, and/or duration of the applied external stimulus or stimuli, the innate properties of the environment where the targets reside, and/or the innate properties of the target chemical compound and/or device.

Stimulation Response (See Energizing Response)

Temporal Activation: See Temporal Response.

Temporal Response: The timing of resonant activation response from a target chemical compound and/or device or structure can be controlled by one or more means, including the timing, strength, and/or duration of the applied external stimulus or stimuli, the innate properties of the environment where the targets reside, and/or the innate properties of the target chemical compound and/or device.

Transformation Response: The response of a resonant nanostructure to resonant activation resulting in the resonant nanostructure transforming or changing its conformation. For example, a structure can change shape and/or geometries by opening and or closing and/or moving the position of the structure's components.

Triggering Response (See activation Response)

Embodiments

In accordance with one embodiment of the present invention, a resonant nanostructure (RNSs) may comprise at least one nanoscaled structure, such as a nanoscaled vesicle or nanoscaled particle, measuring from about 1 nanometer to about 1000 nanometer along at least one dimension. In certain embodiments, the RNS may comprise a microscaled structure larger than about 1000 nanometers in at least one dimension, or a combination of nano- and microscaled structures. The structure, in one embodiment, may have resonant properties and may be capable of generating a resonant response to an external stimulus, such as electromagnetic stimulus or an acoustic stimulus. The resonant response generated by the resonant nanostructure of the present invention can occur within one picosecond to one hour or longer following the stimulus. It should be appreciated that the resonant nanostructure may be made from one or more nanoscaled structures having resonant properties and capable of generating a resonant response.

The resonant response exhibited by an RNS is controlled by one of a time course of a stimulus, strength of the stimulus, local environment, resonant potential of the resonant nanostructure, or a combination thereof. The resonant response of the RNS may result in mechanical fracturing or permit the RNS to remaining intact. RNS structure can comprise fracture regions that determine any of extent and force of fracturing response.

Further, RNS structure may comprise harmonic regions that affect the response, such effects including any of the enhancement and tuning of the resonating response. RNS structure can also comprise electrically-charged regions and/or any of hydrophobic, hydrophilic, or amphipathic regions. RNS structure may comprise magnetically-polarized regions capable of attracting other structures and/or chemical compounds via electromagnetic and/or other forces

RNS structure may comprise a coating that attracts any of cells, chemical compounds, or other resonant structures. The coating can shield underlying structures from the environment, can resonate and/or fracture in response to any of an electromagnetic stimulus or an acoustic stimulus, can attach to cell surfaces or is incorporated within cells to identify molecules or biological structures.

RNSs can be any structure that has resonant properties, as associated variously with physicochemical composition, external structure, and/or internal structure. RNS structure has no cavity has a cavity configured to transport any of a payload or other structure. The mechanical fracturing of an RNS results in the release or exposure of the payload. The resonant response of an RNS can include a transfer of energy that is absorbed by payload, the payload being an inactive compound, the absorption of energy causing the transformation of the inactive payload into an active payload.

RNS structure may be without specialized attachments or may comprise attached compounds, the compounds configured to target other compounds. RNS structure can be configured to trap a chemical compound, cell organelle, or other structure. RNS structure can be configured to assemble chemical compounds from attached chemical sub-compounds. Further, RNS structure can be configured to attach to cell membranes can deliver payloads into the cells.

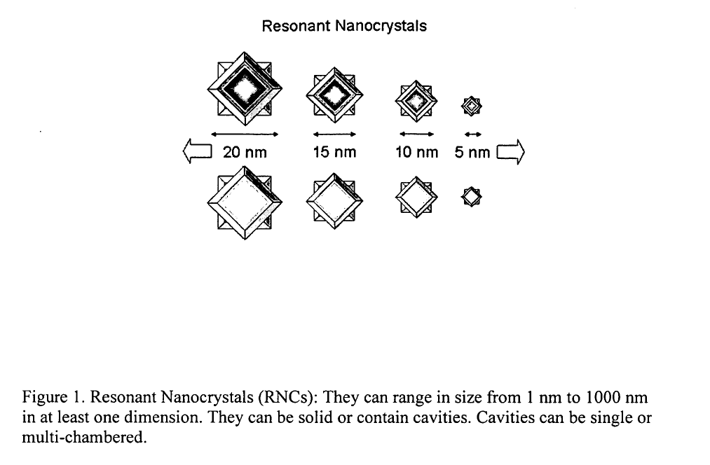

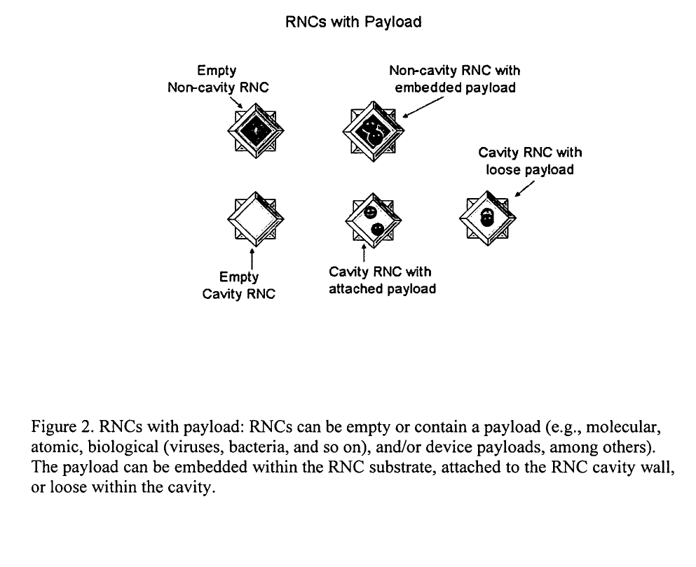

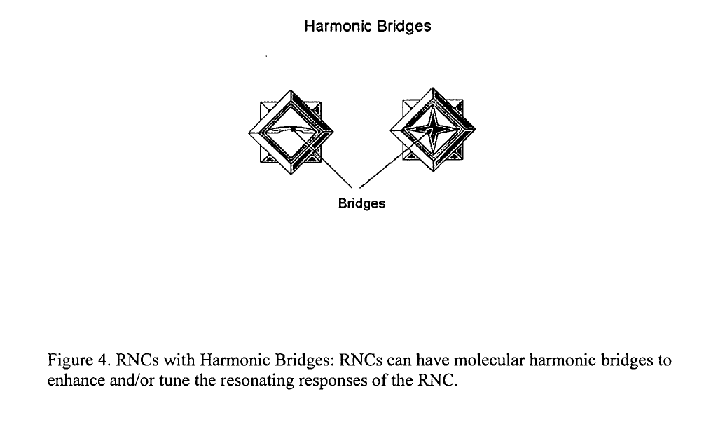

Resonant nanocrystals (RNCs) are RNSs wherein the structure is crystalline. The crystal lattice of an RNC defines its basic internal and external physical structure. This lattice can be composed of elements, such as silicon, carbon, and others. Additional elements and/or molecules can be attached to the lattice, both externally and internally. RNCs include solid forms and cavitated forms; solid forms are termed Non-Cavity RNCs, and those with internal cavities, are termed Cavity RNCs (FIG. 1: RNCs). The cavities can either be empty or they may include a payload therein (FIG. 2: RNCs with Payload). RNCs can be designed with molecular structures that function as harmonic bridges to facilitate and/or tune the RNC resonance (FIG. 4: RNCs with Harmonic Bridges).

Functional Aspects of Resonant Nanocrystals

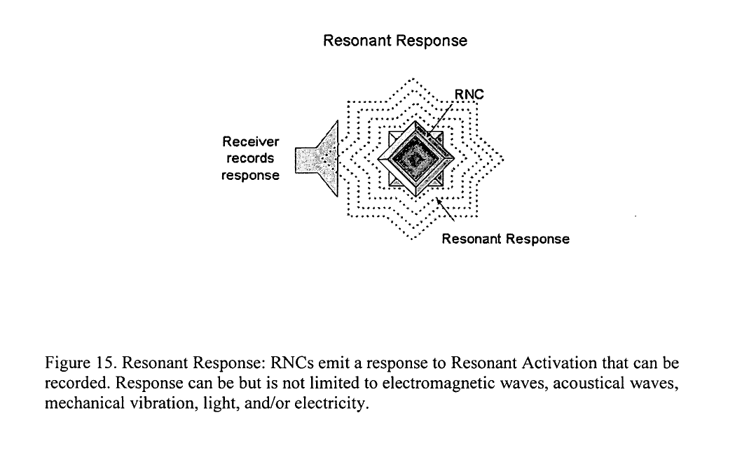

RNCs resonate by resonant activation, which is the application of an electromagnetic or acoustic stimulus or stimuli at or around the resonance frequencies of the RNC (FIG. 15 Resonant Activation). The RNCs resonate based on inherent properties of the crystal lattice, the time course of the stimulus, the strength of the stimulus, the local environment, or the resonant potential of the RNC. Cavity RNCs can also resonate based on the physics of cavity resonance and/or other physical mechanisms. The totality of the ability of an RNC to resonate may be referred to as its resonant potential.

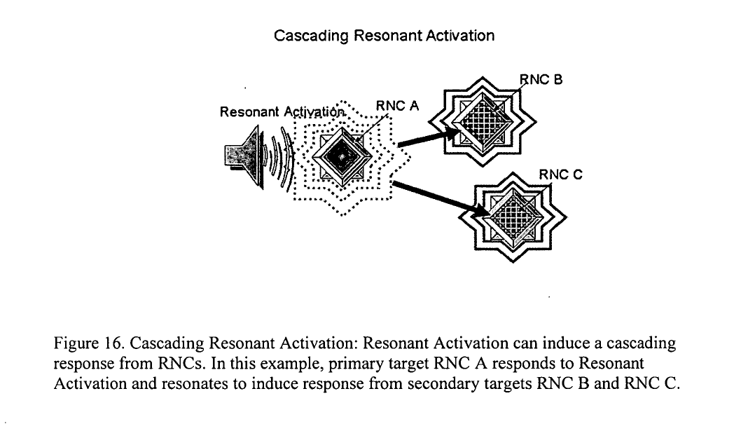

When RNCs resonate, they transmit resonant response waves that can be measured and recorded by medical imaging or other systems (FIG. 16 Resonant Response). RNCs may also release heat, light, electrical energy, and/or vibrate, during resonance.

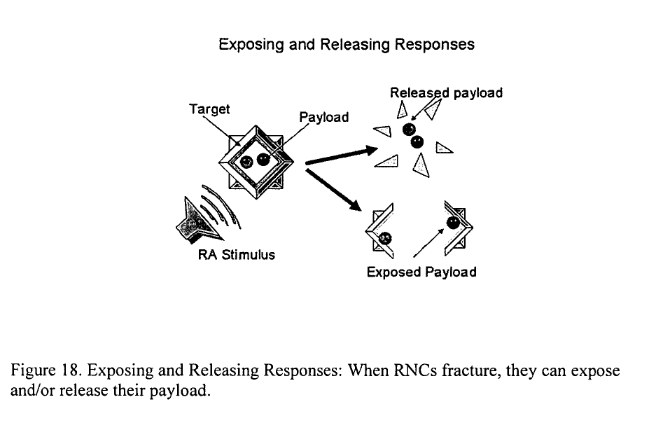

RNCs can be fractured by applying the RNCs resonance frequency from a stimulus or stimuli at sufficient amplitude and duration (FIG. 18 Fracturing Response). The fracturing of an RNC can be destructive or non-destructive to simply release or expose its contents (i.e., its payload).

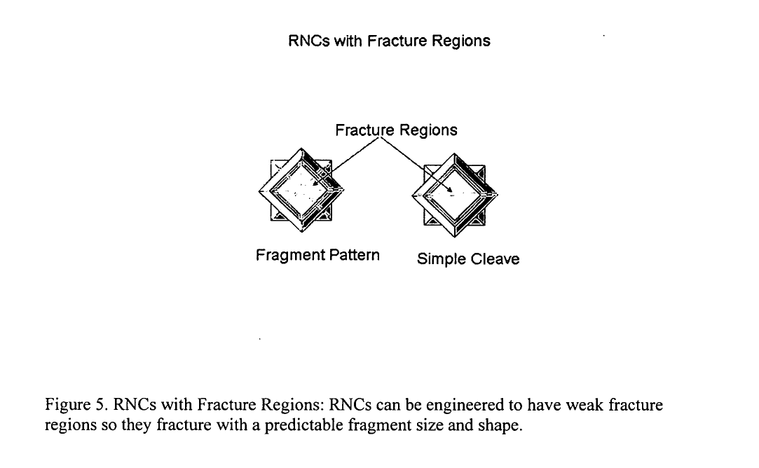

The RNC lattice can be engineered to have weaker regions that will fracture at predefined areas (FIG. 5: RNCs with Fracture Regions). These regions can be designed to make large or small fragments and to determine how “destructive” ihe fracturing effect will be. The size and shape of the RNC “shrapnel” can be engineered to have different effects.

Operational Features of Resonant Nanocrystals

The primary role of RNCs is to operate on individual cells; an RNC may either enter a cell or attach to the cell membrane. Once in contact with target cells, RNCs can perform a variety of operations, inherently and/or as a consequence of being activated by the application of an external stimulus or stimuli.

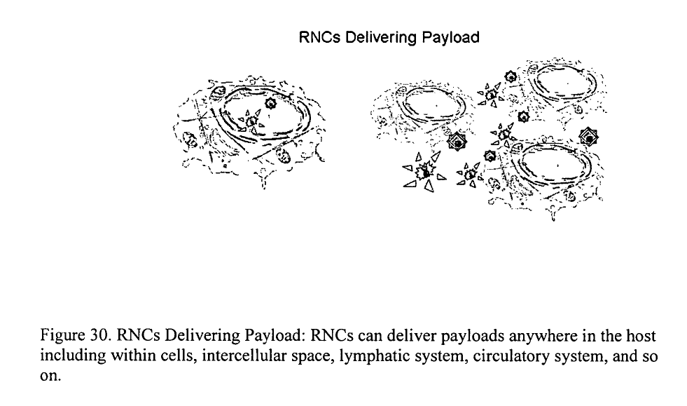

RNCs can be fractured on the surface of or within cells so that the fragments mechanically pierce (lyse) or otherwise disrupt the cell membrane and either damage or kill the cells (FIG. 30: RNCs Lysing Cells). This application of RNCs is potentially an effective, non-pharmaceutical treatment to selectively destroy cancer and microbial cells.

Applying an external stimulus or stimuli to RNCs can also kill or damage target tissues through thermal, electrical, vibrational, or other forces. One effect can be to damage cellular structures, such as the cytoskeleton, to damage or kill the cell and/or prevent mitosis. Another effect may be to interfere with cellular metabolic pathways and/or to induce cell apoptosis (programmed cell death).

Fracturing RNCs can potentially emit electrical current and damage target tissues. Alternatively, this current could be used to stimulate electrical or neural activity.

RNCs can be engineered to fit into specific cell membrane pores like a key fitting into a lock. Their geometry, surface characteristics, size and weight can be controlled through the fabrication process.

Cavity RNCs can carry a payload and deliver drugs, small molecules, genetic material, atoms, viruses, (such as a variant vaccinia virus (vvDD) for targeting tumors) among others. Payloads can be activated by resonant activation, a for example, a payload may change corformation in response to resonant activation, thereby exposing an active region.

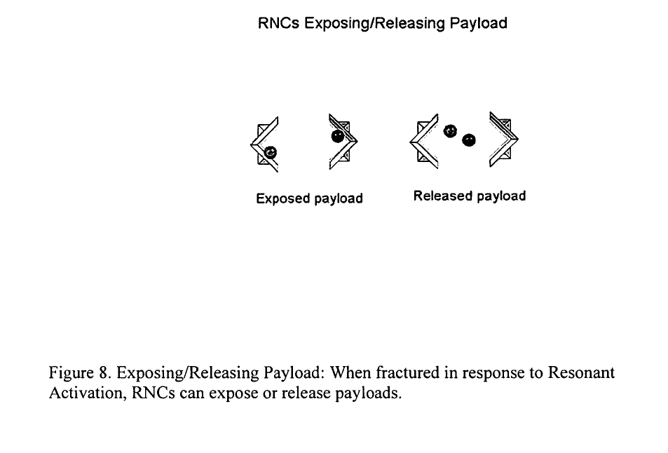

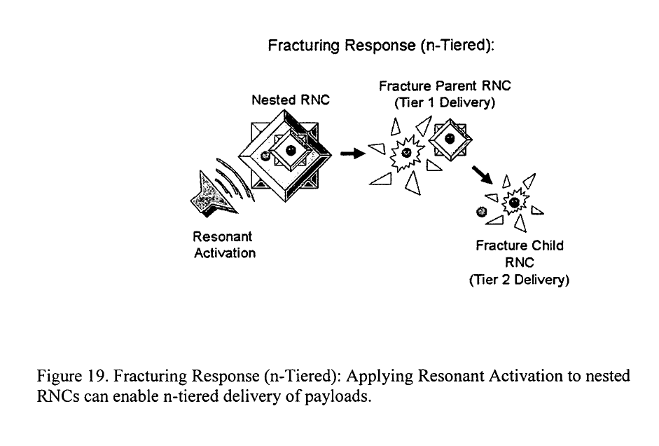

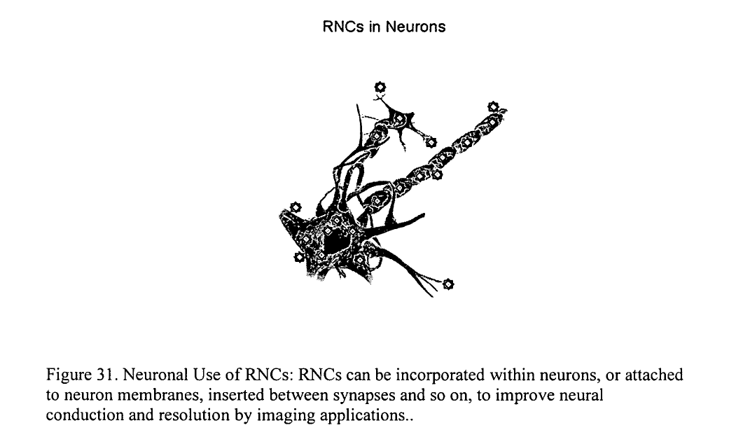

Fracturing Cavity RNCs releases their contents and/or exposes their contents to the target environment, either inside the target cell cytoplasm or into the intercellular space between cells. (FIG. 8 Exposing/Releasing Payload, FIG. 19, Exposing and Releasing Responses, and FIG. 31 RNCs Delivering Payload).

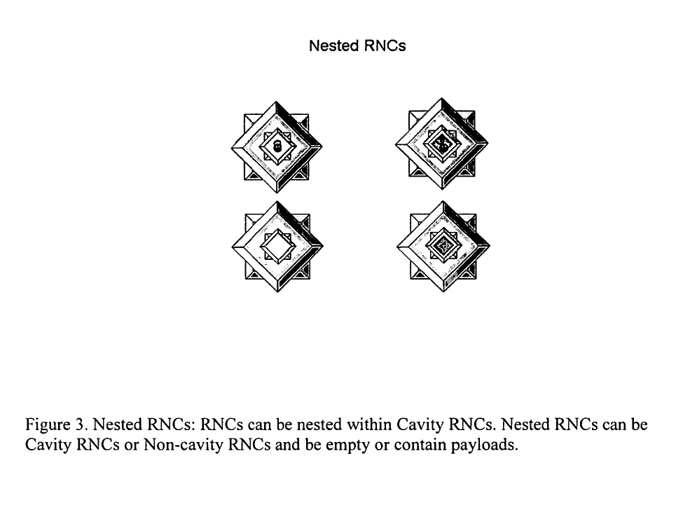

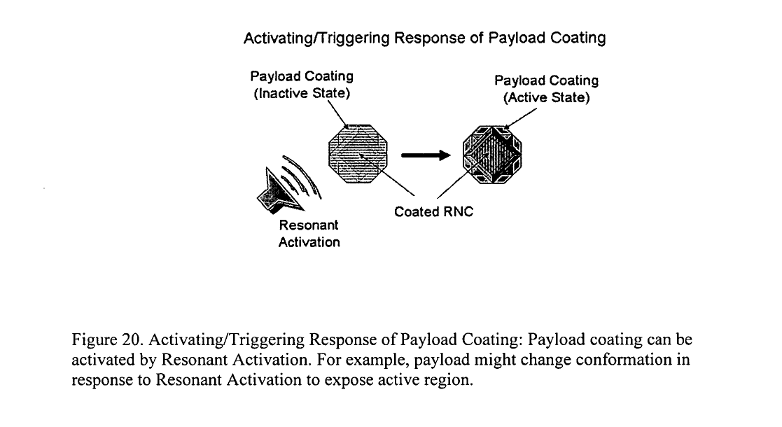

An RNC may also carry one or more other RNCs within its cavity (FIG. 3 Nested RNCs). Such RNCs are called “Nested RNCs” and can enable n-tiered payload delivery (FIG. 20 Fracturing Response (n-Tiered)).

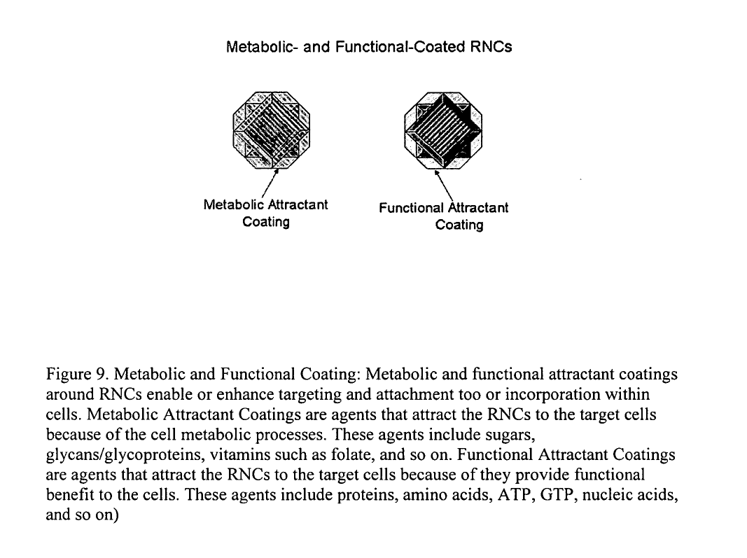

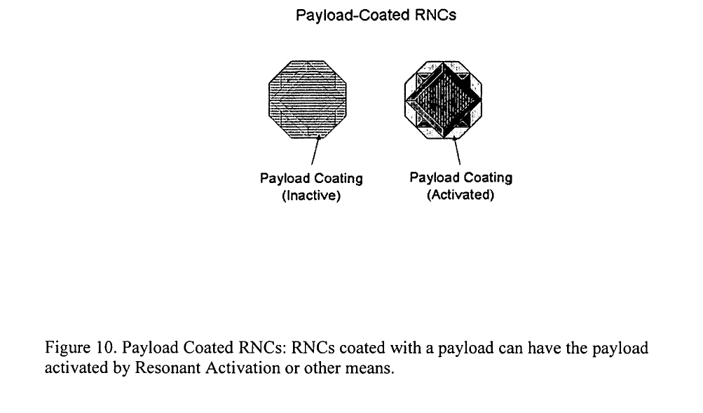

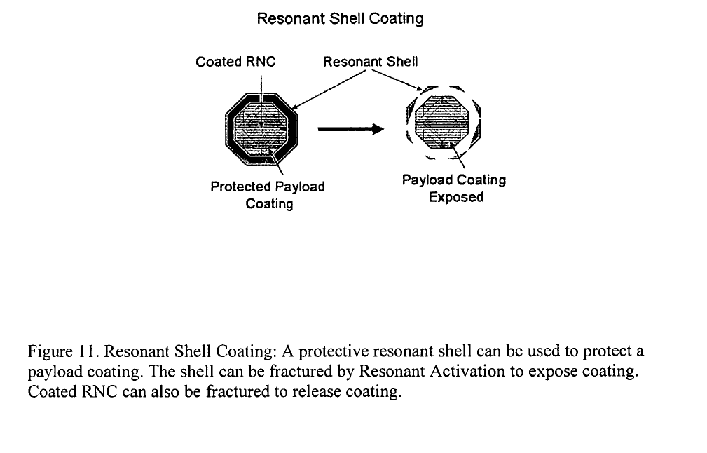

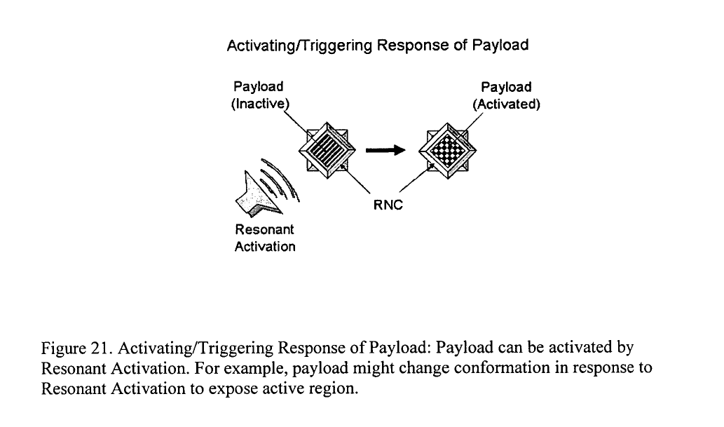

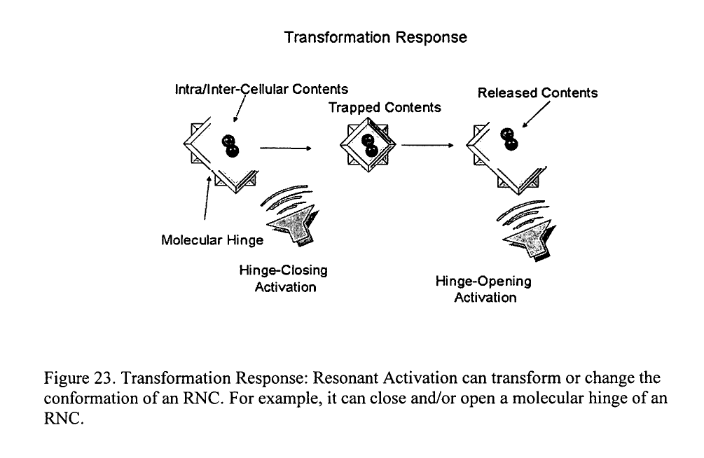

Highly metabolic cells, such as cancer cells will likely incorporate more RNCs than other normal cells. To enhance this process, RNCs can be coated, uncoated, or integrated with “coating” materials (FIG. 9 Metabolic and Functional Coating, FIG. 10 Payload Coated RNCs, and FIG. 11 Resonant Shell Coating). These coatings can also facilitate the retention or clearing of the RNCs from the host. Coatings can be a “metabolic attractant” such as, by way of example, sugars, glycans/glycoproteins, vitamins (such as folate), to encourage their uptake within cells or attachment to cell membranes. RNCs can also be coated with a “functional attractant” with chemical compounds that cells need for development and cell processes, such as, for example, proteins or other molecules including phospholipids, amino acids, nucleic acids, ATP, GTP, and others to encourage attachment to cell membranes and/or uptake within cells. RNCs may be coated with a payload (such as atoms and/or molecules that are to be delivered to the target cells). This payload can be active or inactive. Inactive payload coatings can be activated by resonant activation or other means. For example, payload might change conformation in response to resonant activation to expose active region (FIG. 21 Activating/Triggering Response of Payload Coating). An RNC payload coating may also have a second coating called a resonant shell. This shell can protect a payload coating or keep it unexposed during delivery to the target cells. The resonant shell can be fractured by resonant activation to expose underlying payload coating (See FIG. 23 Fracturing Response of Resonant Shell).

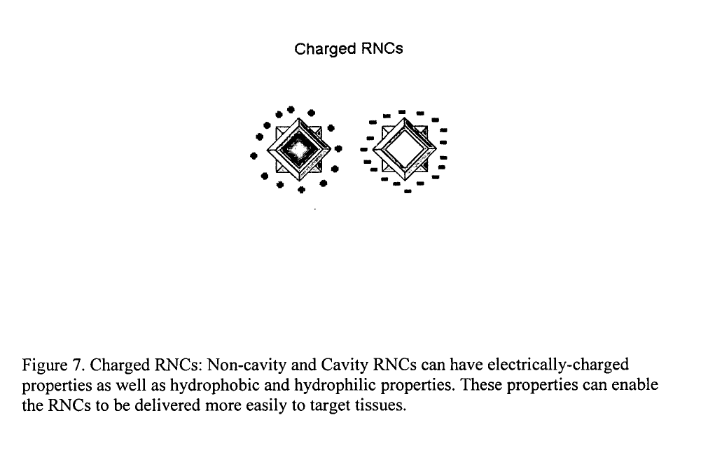

RNCs and/or their coatings or attachments can be hydrophobic or hydrophilic, or have a combination of these features, in which case they are termed amphipathic. RNCs and/or their coatings or attachments also may carry an electrical/ionic charge to encourage or discourage transport, cell absorption or incorporation, and attachment to cell membranes (FIG. 7 Charged RNCs). Once inside a target cell, RNCs can attach to specific cell organelles, structures, and/or chemical compounds within the cell.

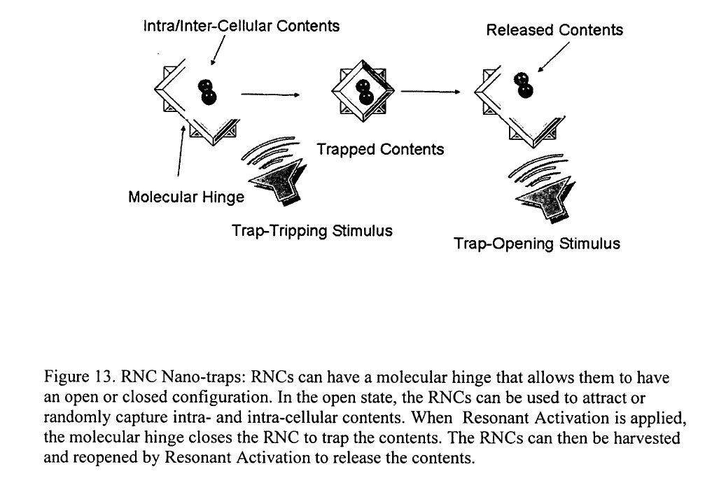

Ligands and other molecules can be attached to the surface of RNCs to bind to specific cell membranes or encourage their absorption within targeted cells (FIG. 13 RNCs with Attached Targeting Molecule(s)). Ligands and other molecules can be attached to the surface of RNCs to bind to specific cell membranes or encourage their absorption within targeted cells. Targeting specific cell membranes, such as those of cancer cells and infectious agents such as bacteria, parasitic organisms, and so on, enables RNCs to be highly-targeted and act as a “smart drug” delivery system.

Cavity RNCs that attach to cell membranes can “inject” payloads into the cell, similar to the way viruses inject nuclear contents. These RNCs are like “naon-vectors” or “nano-vaccines”, or “nano-injectors”.

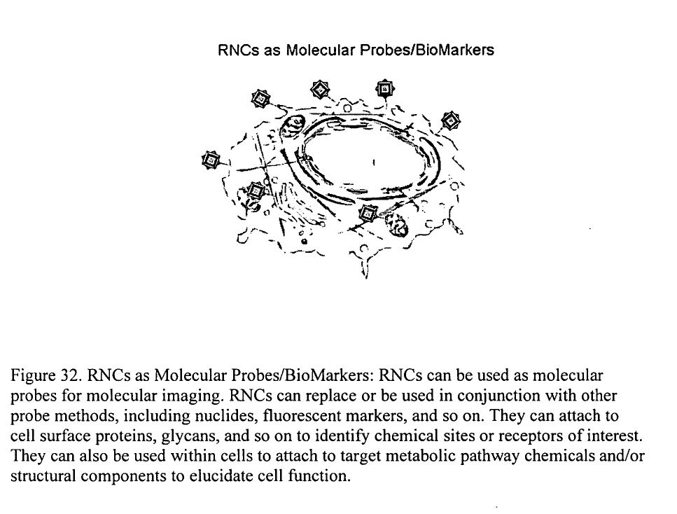

RNCs may further be used as molecular probes for molecular imaging. RNCs can replace or be used in conjunction with other probe methods, including, by way of example, nuclides and fluorescent markers. RNCs can attach to cell surface proteins and glycans, to identify chemical sites or receptors of interest. They can also be used within cells to attach to target metabolic pathway chemicals and/or structural components to elucidate cell function (FIG. 32 RNCs as Molecular Probes/BioMarkers).

Resonant activation (RA) is a method of applying a stimulus or stimuli to targets that include, but are not limited to sub-atomic particles/waves, atoms, molecules, chemical compounds, and/or nano- or micro-scale devices, in vivo and/or in vitro to induce, elicit, or affect a response from the targets.

The response of the targets may include resonating, fracturing or cleaving, exposing, releasing, activating or triggering, de-activating, energizing, exciting, stimulating, de-energizing, de-exciting, de-stimulating, attracting or joining, separating or disassembling, transforming or changing conformation, magnetizing, aligning, positoning or moving, or otherwise changing or altering the target of the stimulus or stimuli.

The nature of the applied stimulus or stimuli may include electromagnetic and/or acoustic forces, such as any of ultrasound, infrasound, microwaves, infrared, magnetic resonance imaging, nuclear magnetic resonance, computed tomography, electron beam tomography, single photon emission computed tomography, positron emission tomography, X-Rays, T-ray (TeraHertz) phonon imaging, as well as others.

Functional Features of Resonant Activation

Resonant Activation induces a resonant and/or other response from targeted chemical compounds and/or nano- or micro-scale devices or structures. The RA stimulus or stimuli transfers energy to (or energizes) the targets to achieve a response. The physical range within which the transfer of energy from the resonating nanostructure to a target may be referred to as the spatial scope of the resonance or resonant response. The spatial scope is a function of the properties of the resonant nanostructure, the local environment, and the target. The totality of the force delivered by resonance activation may be referred to as the magnitude of the response, and this, as well as the spatial scope of the response, is a function of the properties of the nanostructure, the local environment, and the target

The nature of the applied stimulus or stimuli is, but is not limited to, electromagnetic and/or acoustic forces, such as such as any of ultrasound, microwaves, infrared, magnetic resonance imaging, nuclear magnetic resonance, computed tomography, electron beam tomography, single photon emission computed tomography, positron emission tomography, X-Rays, T-ray (TeraHertz) phonon imaging, or others.

The actual response/responses from the targets are based on inherent properties of the targets, the innate properties of the environment where the targets reside, and/or on the nature of the stimulus or stimuli. The following table describes some examples of possible target responses:

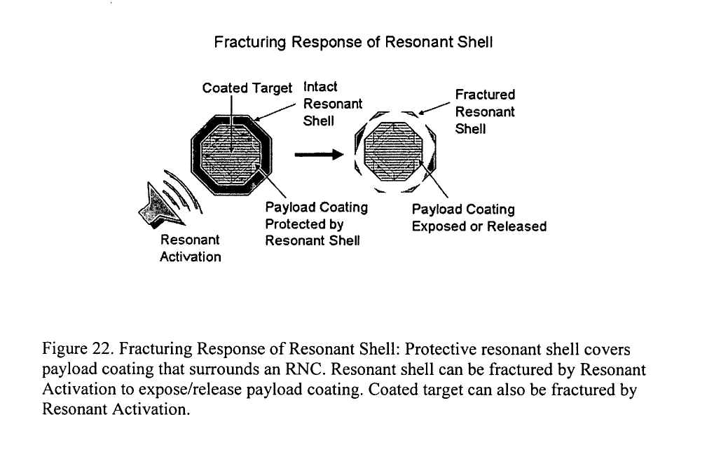

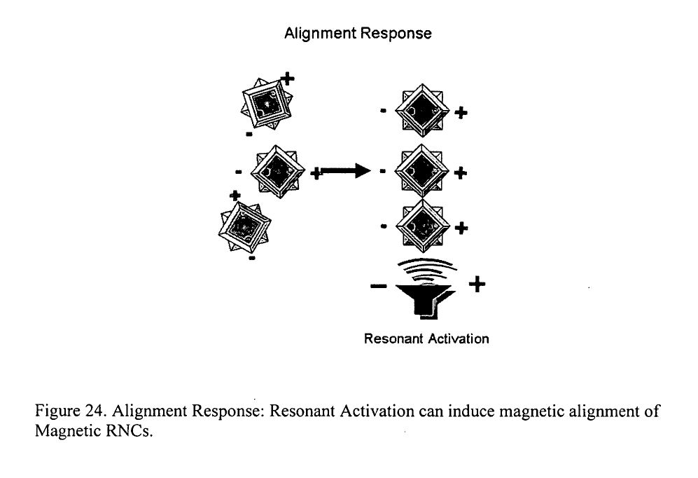

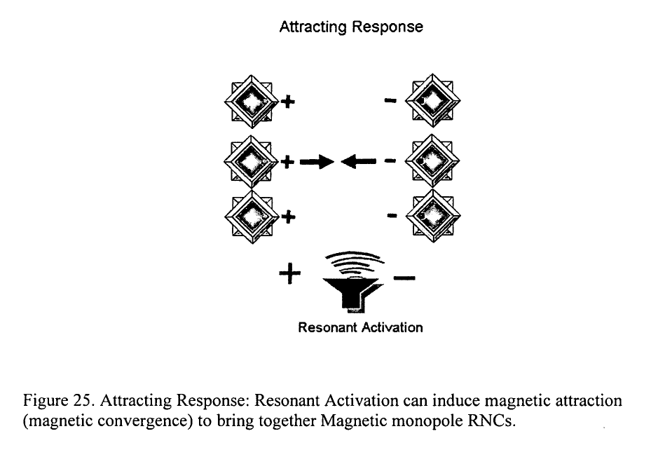

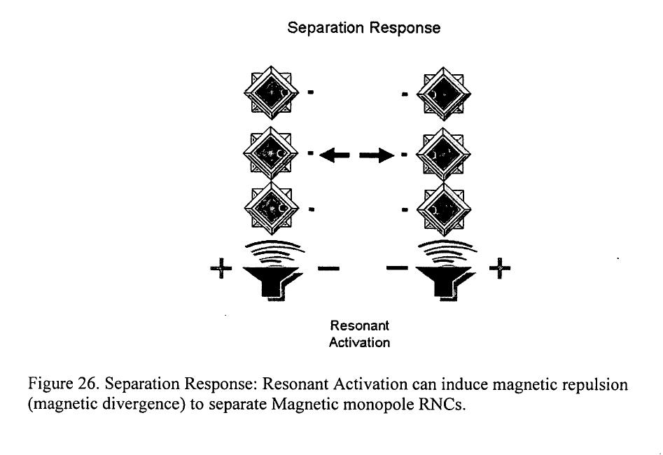

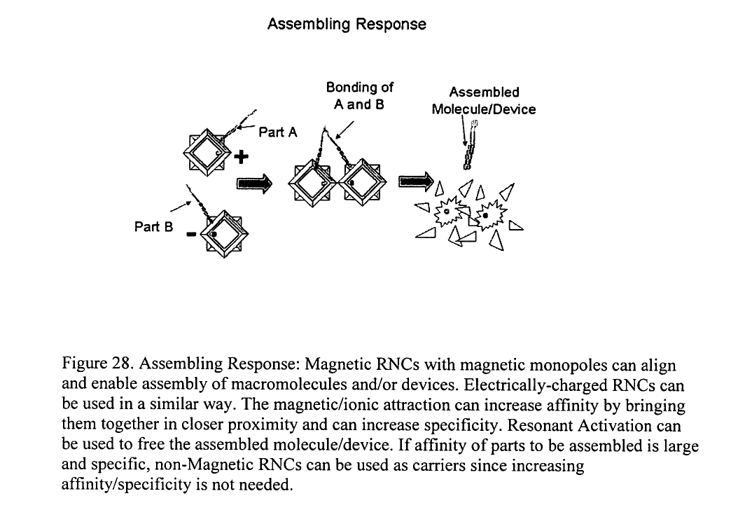

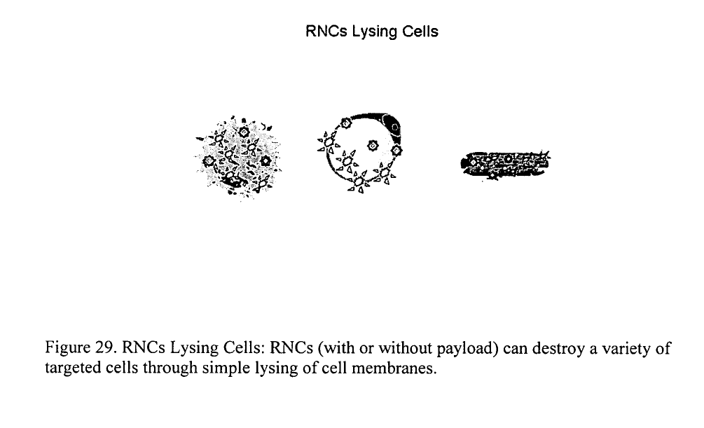

TABLE 1
Various Responses to Resonant Activation of Nanocrystals

| Possible | |
|---|---|
| Response | Description |
| Resonate | Targets respond to RA by |
| | resonating and possibly emitting |
| | electromagnetic, mechanical, and/ |
| | or acoustic energy (FIG. 16 Resonant |
| | Response). |
| Fracture/Cleave | Targets respond to RA by fracturing |
| | into two or more fragments, |
| | magnitude/strength of the fracturing |
| | response on a target chemical |
| | compound and/or device or structure |
| | can be controlled by one or more |
| | means, including the temporal or |
| | spatial activation of the applied external |
| | stimulus, the innate properties of |
| | the environment where the targets reside, |
| | and/or the innate properties of the |
| | target chemical compound and/or |
| | device. (FIG. 18 Fracturing Response, |
| | FIG. 20 Fracturing Response (n- |
| | Tiered), and FIG. 23 Fracturing |
| | Response of Resonant Shell). |
| Expose | Targets respond to RA by exposing |
| | structures and/or contents to the |
| | containing environment. For example, |
| | targets that carry fixed payloads can |
| | expose these payloads upon fracturing |
| | or cleaving. (FIG. 19 Exposing and |
| | Releasing Responses). |
| Release | Targets respond to RA by releasing |
| | structures and/or contents to the |
| | containing environment. For example, |
| | targets that carry loose payloads |
| | can release these payloads upon |
| | fracturing or cleaving. (FIG. 19 Exposing |
| | and Releasing Responses) |
| Activate/Trigger | Targets respond to RA by changing |
| | from an inactive state or form to an |
| | active one and/or triggering another |
| | response. For example, an inactive |
| | chemical compound can activate by |
| | revealing/exposing an active site for |
| | binding with other chemical compounds, |
| | device or structure, tissues, and |
| | so on. For example, a device or struc- |
| | ture can activate by switching from an |
| | Off state to an On state, or becoming |
| | operationally active based on its |
| | intended design (FIG. 21 Activating/ |
| | Triggering Response of Chemical |
| | Payload Coating and FIG. 22 Activating/ |
| | Triggering Response of Payload). |
| De-Activate | Targets respond to RA by changing |
| | from an active state or form to an |
| | inactive one. For example, an active |
| | chemical compound can de-activate |
| | by hiding an active site for binding |
| | with other chemical compounds, device |
| | or structure, tissues, and so on. |
| | For example, a device or structure can de- |
| | activate by switching from an on- |
| | state to an off-state, or becoming |
| | operationally inactive, based on its |
| | intended design. |
| Energize/Excite/ | Targets respond to RA by becoming |
| Stimulate | energized, excited, or stimulated to a |
| | higher potential energy state, thereby |
| | enabling them to release energy in |
| | the form of heat, emit electrical energy, |
| | emit light, and/or vibrate, among |
| | others. |
| De-Energize/De- | Targets respond to RA by becoming de- |
| Excite/De- | energized, de-excited, or de- |
| Stimulate | stimulated to a lower potential energy |
| | state, thereby reducing their ability to |
| | release energy. |
| Attract/Join/ | Targets respond to Resonant Activation |
| Assemble/ | and Resonant Activation by |
| Converge/ | attracting or joining. This attraction |
| Conjoin/Merge | can include, but is not limited to, |
| | magnetic attraction, ionic attraction, |
| | atomic force attraction, |
| | hydrophilic/hydrophobic forces, among |
| | others (FIG. 29 Assembling |
| | Response and FIG. 26 Attracting |
| | Response). |
| Separate/Repulse/ | Targets respond to RA by separating |
| Disassemble/ | or disassembling. This separation |
| Diverge | can include, but is not limited to, |
| | magnetic repulsion, ionic repulsion, |
| | atomic force repulsion, hydrophilic/ |
| | hydrophobic forces, among others (FIG. |
| | 27 Separation Response) |
| Transform/Change | Targets respond to RA by transforming |
| Conformation | or changing their conformation. For |
| | example, a target can change shape |
| | and/or geometries by opening and/or |
| | closing and/or moving the position |
| | of the target's structural components |
| | (FIG. 24 Transformation Response). |
| Magnetize | Targets respond to RA Resonant |
| | Activation by becoming magnetized and |
| | thereby responding to magnetic |
| | forces (FIG. 28 Magnetic Induction). |
| Align | Targets respond to RA by aligning |
| | with other targets along a spatial |
| | plane. (FIG. 25 Alignment Response) |
| Position/Move | Targets respond to RA by moving to |
| | a specific position. For example, |
| | targets can be positioned to a specific |
| | target tissue and/or region of the host. |

Application of the RA stimulus or stimuli can be in vivo, such as in a host animal, subject, or patient. It can also be applied in vitro, such as in a test tube, micro-array, nano-array, or other vessel containing targets to be affected by the RA stimulus or stimuli. RA can induce, elicit, or affect a response at the atomic level, molecular level, cellular level, tissue level, organ level, and/or system level.

RA can penetrate living tissue to invoke a response in the target chemical compound and/or device.

The timing of RA response (i.e., the temporal response) from a target chemical compound and/or device or structure can be controlled by one or more means, including the timing, strength, and/or duration of the applied external stimulus or stimuli, the innate properties of the environment where the targets reside, and/or the innate properties of the target chemical compound and/or device.

The spatial location or scope of the response (or the spatial response) from a target chemical compound and/or device or structure can be controlled by one or more means, including, for example, the position, proximity, angle, strength, and/or duration of the applied external stimulus or stimuli, the innate properties of the environment where the targets reside, and/or the innate properties of the target chemical compound and/or device.

The magnitude or strength of the response (known as the magnitude response) from a target chemical compound and/or device or structure can be controlled by one or more means, including but not limited to the temporal and spatial activation of the applied external stimulus or stimuli, the innate properties of the environment where the targets reside, and/or the innate properties of the target chemical compound and/or device.

RA can induce, elicit, or affect a response from the targeted chemical compounds and/or devices or structures generally within one picosecond to one hour, but depending on the nature of the activation, it make take longer.

Operational Description of Resonant Activation

The primary role of resonant activation is to induce, elicit, or affect responses from targeted chemical compounds and/or nano- or micro-scale devices or structures in vivo and/or in vitro. Depending on the location of the targets, RA can operate at the atomic level, molecular level, on individual cells, groups of cells, tissues, organs, and at the systems level.

RA can improve the quality of medical images by one or more means, including but not limited to, increasing the signal to noise ratio, improving spatial resolution, improving temporal resolution, adjusting contrast, reducing imaging artifacts, and so on. RA can improve imaging and diagnostic techniques at the atomic level, molecular level, cellular level, tissue level, organ level, and/or systems level.

RA can enable real-time, in vivo identification and/or diagnoses of disease states and other health conditions, and determine their location and extent, including, by way of example, cancer and related diseases, parasitic infections, microbial infections, coronary artery disease, neurological disorders, metabolic disorders.

RA can enable real-time in vivo, targeted treatment of diseases and other health conditions, including, by way of example, cancer and related diseases, parasitic infections, microbial infections, coronary artery disease, neurological disorders, metabolic disorders.

RA can enable real-time confirmation of the effectiveness and/or completeness of the response from targeted chemical compounds and/or structures of devices. RA can also enable real-time confirmation of the effectiveness and/or completeness of treatment for disease and other health conditions.

RA can enable real-time measurement of biological function and processes, including, by way of example, to temporal, spatial, mechanical, electrical, and chemical measurements. It can also enable real-time measurement of neurological function, processes, and/or neural conduction (FIG. 31 Neuronal Use of RNCs).

RA can enable assembly and/or a attracting of chemical compounds and/or devices or structures through magnetic and/or other means. It can also enable disassembly and/or a separating of chemical compounds and/or devices or structures through magnetic and/or other means.

### EXAMPLES AND METHODS

Resonant nanocrystals provide a new family of materials for diagnosing and treating a wide range of diseases and health conditions. The following sections provide examples of the possible applications for RNCs, and in many cases, why they may be superior to conventional methodologies and approaches.

Cancer Diagnostics and Therapies

The current cancer therapies, particularly chemotherapeutic approaches have limitations and features that make them less than completely satisfactory. Most anti-cancer drugs are nonspecific and can kill healthy cells, including those of the immune system cells. The treatment itself can be life threatening by making the patient susceptible to secondary infections. Similarly, radiation therapies are non specific and can damage healthy tissues to the detriment of the patient.

In terms of their temporal aspects, the application of a chemotherapeutic drug provides little control of the timing of when the drug affects the target cancer cells. The timing depends on many factors including the nature of the drug itself, its absorption profile and elimination profiles, and the metabolic health of the patient. Because of these factors and the complications of side effects, chemo-therapies must be carefully administered and monitored to achieve maximum benefit with minimum detrimental effects on the patient.

Finally, chemo-therapeutic cancer therapies have limited effect on CNS malignancies because they cannot cross the blood/brain barrier.

RA technology and RNCs provide a solution to the various shortcomings of currently available therapies as outlined above. RNCs can be targeted to affect specific cell types, specific membrane profiles, specific metabolic cell profiles, and others.

Unlike traditional chemotherapies, RNCs may be temporally activated. They can be administered, absorbed within target cells, and then temporally activated through the application of an external stimulus or stimuli.

RNCs can also be imaged using resonance activation to confirm their targeted specificity and concentration before they are fully activated to affect the targeted cells.

RNCs themselves are generally non-toxic to the host. If they are delivering cytotoxic payloads, they are toxic only to targeted cells when temporally activated. Base RNC lattice materials are inert, consisting of silicon, and other elements.

RNCs can be fractured inside target tissues so they can be easily eliminated by the body via the kidneys, macrophages, and/or liver. Fragment sizes can be predetermined and controlled during the fabrication process.

Finally, unlike conventional chemotherapies, RNCs can be small enough (5 nm) to deliver drugs across the blood/brain barrier.

Anti-Microbial Diagnostics and Therapies

The term “microbe” covers a wide range of organisms, including bacteria, viruses, fungi and molds, protozoa, and multi-cellular parasitic organisms. Certain anti-microbial therapies have limited targeting and specificity capabilities. They can adversely affect healthy tissues as well as the targeted microbial cells. For example, broad spectrum antibiotics can kill healthy and necessary bacterial flora within the host, which can lead to other health problems and unwanted side effects.

Certain anti-microbial therapies can cause allergic reactions in some patients, making them unusable, and in the worst cases, life threatening. Current anti-microbial therapies often create drug resistant strains; this problem, in particular, limits the long-term viability of the treatment regimens, and shortens the time the drug will be an effective anti-microbial agent. Further, current anti-microbial therapies cannot be temporally controlled or activated; i.e., once administered, they begin working. Their effectiveness depends on many factors including the nature of the drug itself, its absorption profile, its elimination profile, and the metabolic health of the patient.

RNCs and RA provide a targeted and temporally-activated way to deliver anti-microbial treatments. RNCs are non-toxic to host cells and can be designed to be toxic to targeted microbial cells when temporally activated by an external stimulus.

RNC lattice materials are inert and non-toxic, consisting of base elements like silicon, carbon, and others. They can be fragmented to be small enough (5 nm-15 nm) to be eliminated by the body via the kidneys, liver, and macrophages.

RA can be used to activate RNCs or other targets to selectively eliminate/kill bacterial and other microbial infections from the host, including blood and lymphatic disorders like sepsis and possibly malaria and other parasitic diseases.

RNC targets of RA are non-pharmaceutical. They can deliver pharmaceuticals, but are not pharmaceutically active themselves. Because of this, microbes can not develop resistance to RNCs and RA therapy.

RA targets (such as RNCs and others) can be used as synthetic antibodies by coating them with ligands or other substances to attach to specific antigens, such as bacterial or viral proteins. In the blood stream, the RNCs can bind to the foreign antigens and improve macrophage/T-Cell phagocytosis.

RA targets (such as RNCs and others) can also be used to bind to foreign microbes within the host circulatory system and gastrointestinal system so the microbes can be more easily eliminated by the host.

Chelation Therapies

Conventional chelation therapies used to eliminate heavy metals and other chemicals from the body can have adverse side effects on the patient, such as toxic and allergic reactions. They are also limited in their effectiveness since they can only penetrate certain tissues and chelate substances that have not been incorporated within cells. RNCs can be used as chelating agents by binding to chemicals and elements within the blood, digestive system, and target tissues of the host For example, RNCs could be used to chelate iron, lead, and organic contaminants.

Drug Delivery

Once a drug is administered, its timeline is activated, and there is little or no control of when and where drug is delivered. The timeline for delivery is pre-determined based on absorption rates, metabolic processes, and other processes. Concentration of delivered drug to desired tissues is also dependent on these processes. There is no way to confirm the drug has reached the desired target tissues and in what concentration it is. It is also not possible to confirm the involvement of non-target tissues by the drug.

Targeted, specific, and temporally activated. Temporal activation means that the timeline of activating targets such as RNCs on target tissues is determined by the individual controlling the activation process. Specifically, RNCs can be activated at will by the application RA. In fact, RNC or other targets can lay dormant and inactive within target tissues until they are either activated by RA or other process, or eliminated by natural cell processes.

RNC targets of RA, and the focus/nature of RA itself, can be targeted for specific cell types, and absorbed within these cells and/or attached to cell membranes. Non-targeted cells are either not affected or minimally affected. RNCs carrying a payload (such as a drug) can release their within the cell, intercellular space, or plasma depending on the targeted location of the RNC.

The extent of the incorporation and effectiveness of targeting can be determined before RA is applied to fracture an RNC or other target or release/expose its contents. In fact, by using RA and or other mechanism, imaging techniques can pre-determine whether or not the RNCs or other targets have reached the target tissues, whether or not non-targeted tissues are affected, and the concentration of RNCs or other targets within tissues. This gives the medical professional control over when to apply RA at sufficient frequency, magnitude, and duration to induce the desired treatment effect. The medical professional can pre-determine the effect and potential side effects of the treatment. The timeline for delivery and activation is determined based on RA as determined by the practitioner.

RNC or other targets can be administered via various mechanisms, including oral, intra-gastric, intravenous, intra-arterial, and intra-lymphatic, transdermal, and directly into cerebral spinal fluid, among others.

RNCs can carry other RNCs (thus, “nested” RNCs), to effect a multi-stage delivery of RNCs and their contents (if any) through the application of RA (FIG. 20 Fracturing Response (n-Tiered)). This approach can be used to achieve a Trojan horse effect by having the parent RNC pass through one tissue and then release the second stage RNC into another tissue. This approach can also enable n-tiered drug delivery. For example, a larger cavity RNC can contain a drug payload and a second-stage smaller RNC that contains a second payload. Each RNC can be engineered to have its own resonance frequency such that they can be temporally activated at different times by applying different resonance frequencies, strengths, and durations.

RA and RNCs for In Vivo Assembly of Chemical Compounds

There are few or no currently viable technologies that enable the in vivo assembly of chemical compounds. RA and RNCs or other targets can be used to carry sub-components of chemical compounds including, for example, drugs and/or molecules into a host. Once within the targeted area, the RNCs can be used to assemble larger molecules by joining the RNCs magnetically, mechanically, or by other means. The RNCs or other targets can be designed to fit together like a jigsaw puzzle and once the assembly is finished, the RNC lattice can be fractured using RA to release the assembled chemical compound.

Neural Diagnostics and Therapies

Electrically-conductive and/or magnetic RNCs or other targets that are absorbed within neurons can improve conductivity of neurons. This can be used to treat neurodegenerative diseases and injuries that impair neural conduction. In particular, diseases such as multiple sclerosis and related diseases that cause motor neuron demyelination could be treated with RNCs or other targets and the possible application of RA. (FIG. 31 Neuronal Use of RNCs).

RA and RNCs or other targets can be used to deliver drugs and other contents across the blood/brain barrier. This application can be used to treat a wide range of CNS diseases, including Parkinson's disease, MS, ALS, and prion-based diseases.

Neural Enhancement

Neural systems, including butnot limited to sensory and motor neurons can be enhanced by integration of or association with resonant nanostructures. For example, detection and response of sensory neurons to external stimuli (such as but not limited to auditory stimuli) can be improved by resonant nanostructures. Such application can be used to improve hearing or perhaps enable auditory perception in areas of the body not usually associated with auditory detection. This application may even enable the detection of non-auditory stimuli, such as detecting other forms of electromagnetic forces not normally detectable.

Nano-Cage for Time-Released Payload Delivery

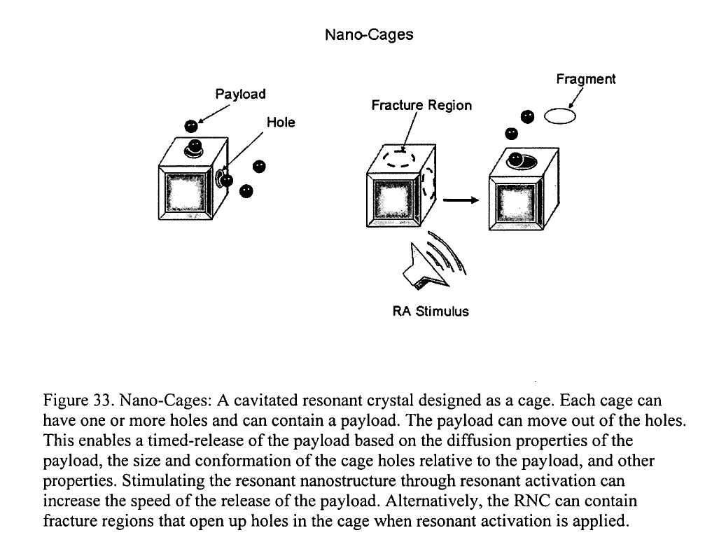

Resonant activation of a cavity resonant nanocrystal can release or expulse a payload by fragmenting the RNC. Alternatively, the cavity resonant crystal can be designed as a cage (FIG. 33). Each cage can have one or more holes and can contain a payload. The payload can move out of the holes. This enables a timed-release of the payload based on the diffusion properties of the payload, the size and conformation of the cage holes relative to the payload, and other properties. Stimulating the resonant nanostructure through resonant activation can increase the speed of the release of the payload. Alternatively, the RNC can contain fracture regions that open up holes in the cage when resonant activation is applied. Instead of fracturing the entire RNC, exposing or releasing is payload, the resonant activation fractures portions of the RNC, thereby opening more and more holes in which the payload can escape the RNC. This enables more precise control over the time-release curve of the payload.

Medical Imaging

Existing medical imaging techniques (including, by way of example, ultrasound, infrared, MRI, CT, X-Rays, EBT) have limitations with respect to spatial resolution, temporal resolution, contrast, and artifacts. This is generally referred to as the sensitivity of the imaging technique. For example, ultrasound scans only show innate density of scanned regions and contrast is limited based on ultrasound frequencies. Dyes and other chemicals and complex computer algorithms are used to increase contrast and resolution with moderate success. There are inherent risks to using contrast dye techniques, including albrgic reactions and side effects. Complex calculations used to improve resolution also take a long time to perform and have limited effectiveness.

One of the most significant limitations for current imaging is that it is difficult to identify diseased issue from healthy tissue. The imaging is not effectively targeted to the diseased areas. This is generally referred to as the specificity of the imaging technique. Significant expertise is required by a radiologist to analyze the results of these images and identify potential diseased sites. Also, the resolution of current techniques and the signal-to-noise ratios of tissues make it difficult to image small lesions. In fact, early-stage cancers are virtually undetectable and must grow to sufficient size before than can be detected. Cancer patients who have been treated for the disease cannot be certain that the cancer has been completely eliminated. Thus, the term remission instead of cure is used simply because the current resolution of diagnostics cannot detect these small tumors. Unfortunately for the patient with fast growing and metastasizing cancers, this limited diagnostic ability means that treatment is usually started too late for an effective outcome.

RA with RNCs or other targets can improve contrast, spatial resolution, and temporal resolution in current imaging technologies (such as ultrasound, infrared, MRI, CT, X-Rays, EBT, and so on), and emerging imaging technologies, such as phonon (THz) imaging. This added resonance can improve the resolution of targeted tissues and reveal details not possible with traditional techniques. Given the nanometer length scale of RA, imaging can break the current resolution barriers for cancer detection and detect small tumors before they become life threatening.

RNCs or other targets that are absorbed within neurons or attached to the surface membranes can enable improved imaging of CNS structures. Further, electrically-conductive and/or magnetic RNCs that are absorbed within neurons or attached to the surface membrane can enable MRI scans (or other imaging techniques) to record neural conduction and temporal properties of neural function, not just neural anatomy. RA can be used to enhance/activate the conductive and/or improve the imaging results (FIG. 31 Neuronal Use of RNCs).

RNCs or other targets and RA can also be used to improve contrast resolution of cardiovascular imaging by attaching to calcium deposits and other atherosclerotic lesions.

Cardiovascular Therapies

RNCs or other targets can be used to bind to arterial plaque and disrupt or remove it at the molecular level via RA. This disruption helps clear arteries affected by atherosclerosis but avoids breaking off large chunks of plaque that can cause further blockage or strokes.

RNCs or other targets can also be targeted and activated by RA to improve electrical conduction for damaged heart pacemaker tissues. RNCs or other targets can also be used to administer a defibrillating electrical charge to target heart tissues via RA.

Cosmetic Therapies

Current techniques require surgery and liposuction techniques to reshape or remove unwanted tissues. Surgery carries inherent risks and long recovery times.

RA and RNC or other targets can be used to eliminate unwanted target tissues including fat cells, tumors, and other cells at the cellular level. By removing tissues at the cellular level, there is less recovery time, less chance of infection since there are no incisions, and little or no scarring, since only the target tissues are affected.

RA and RNCs or other targets can be used to administer chemicals and nutraceuticals to the skin for cosmetic treatments and therapies. Targets can be applied directly to the skin or via a transdermal gel and activated by RA.

Wound/Incision Closure

Current wound closure techniques require stitches, tapes, or glues. These conventional approaches are effective, but they also leave varying levels of scarring. There may be circumstances, such as wounds in the battlefield, or particular kinds of wounds that can benefit from RNC-based wound closure.

Resonant activation can be used to close wounds and incisions from surgical procedures (resonant activation wound closure). The nature of the RA and RNCs or targets may be magnetic or may be to induce some other attracting property such as adhesive qualities of the targets and tissues. The RNCs or other targets are applied to the wound/incision, they are incorporated into the wound/incision margins, and resonant activation then is used to activate the targets to draw them and the tissues together to seal the wound/Ancision. The wound/incision can be reopened or expanded by reversing or removing the attractive effect of the RA. This approach can be used to replace traditional forceps, hemostats, and other mechanical medical tools.

Once the wound/incision is healed, the magnetic chemical compounds and/or devices or structures can be eliminated from the wound tissues normal biological processes. In the case of resonant nanocrystals, the devices or structures can be optionally fractured in-situ using resonant activation to facilitate their elimination by the host.

Advantages of RNCs Compared with Organic Nano-Particles and Nano-Vesicles

Other technologies and materials on the nano-scale are under development for cancer and other therapies. These include organic micelles, dendrimers, and multiple-membrane vesicles that can deliver chemotherapeutic agents within cells. Organic-based nano-particles and nano-vesicles are dependent on cellular processes to release their contents into cells. For example, membrane-based vesicles require the outer and inner membranes be dissolved within the cell, and the timing and efficiency of this process cannot be controlled externally.

Like these techniques, RNCs can deliver drugs and chemotherapeutic agents within cells, however, RNCs have the advantage of being temporally-activated activated by an external stimulus.

RNCs can be manufactured in large quantities without the need for large-scale biotech manufacturing facilities. In fact, industry-standard semiconductor fabrication facilities can be easily configured to fabricate RNCs. The manufacturing process also ensures near 100% yield on a predictable and short timescale when compare to traditional biotechnology manufacturing approaches.

Advantages of RNCs Compared with Silicon-Based Nano-Particles, Nano-Rods, Nano-Dots, and Coated Nano-Shells

Other technologies and materials, including quantum dots and coated nano-shells, such as nylon beads coated with gold, are being developed for medical imaging and therapies for cancer and other diseases. Quantum dots are silicon-based nano-particles that are manufactured to be bio-inert and stable, but also provide visible-spectrum fluorescent imaging within target tissues. Their use is limited in vivo because the visible-spectrum light emitted from these particles can only penetrate thin cell layers of approximately 1 cm. Coated nanoshells, such as nylon beads or other particles coated with gold and other metals, are not easily targeted for specific tissues. They also only provide one mechanism for damaging target tissues, namely heat.

RNCs can provide cellular and tissue-level imaging through established tomographic 3D techniques using resonance without the need for potentially harmful fluorescent chemicals and dyes. Unlike quantum dots, RNCs can be fractured within the target tissues to facilitate their elimination from the host through kidneys, liver, and macrophages, and others.

RNCs can be resonantly excited to have a variety affects on target tissues. These include, merely by way of example, heat, electrical energy, mechanical fracturing, vibration, and delivery of payloads.

RA for Cellular-Level Medical Applications

This section provides some examples of the possible medical applications enabled or improved by RA.

RA and RNCs or other targets can enable real-time diagnosis and treatment of diseases, including but not limited to cancer and other malignancies. Specifically, RNCs or other targets can be administered to a patient. The amount of incorporation of the RNCs/targets and their location in the patient can indicate the extent of the disease. Once incorporated into the target diseased tissues, the RNCs/targets can be temporally activated via RA to affect the tissues as desired. In the case of cancer, the effect is likely to kill and/or damage the cancer cells so they can be eliminated from the body. The RNCs/targets can then be eliminated by the host normal processes.

RA and RNCs or other targets can be use in vivo to selectively destroy cancer and microbial cells (bacteria, protozoa, and so on) and eliminate such cells from an animal or human host. This technique can also be used to target multi-cellular parasites.

RA and RNCs or other targets can be use in vitro to selectively destroy cancer and microbial cells and eliminate such cells from cell cultures and other cell suspensions, including those used for bone marrow transplants and blood transfusions.

RA and RNCs or other targets can destroy cancer cells and microbial cells from within the cell and/or by attaching to the membrane of the cell. The mechanism of cell death results from simple mechanical lysing of the cell membrane, the delivery of cytotoxic atoms or molecules, such as silver ions, oxygen, ozone, or other substances, or the mechanical disruption of the cytoskeleton or disruption of other cellular ultrastructure or processes through vibration, heat, electricity, desiccation, or other mechanism.

RA and RNCs or other targets can be used for drug delivery to transport atoms, small molecules (including RNA or DNA fragments), viruses, bacteria, and/or partially assembled larger molecules, among others directly into cells. These RNCs thus act like nano-pills, and can deliver contents internally within cells, to the surface of membranes, within the intracellular or interstitial space, and within the vascular and lymphatic vessels.

RNCs or other targets can be engineered to be less than 5 nm in dimension. As such, they can deliver contents across the blood brain barrier, either directly or via lysosome formation or other mechanism. These RNCs/targets can be used to treat disease states, such as malignancies, infections, and neurodegenerative diseases, including prion-based diseases, within the CNS by delivering drugs andbr by resonating to destroy cells mechanically, by heating, electrically, or other mechanism. The targets can be activated by RA.

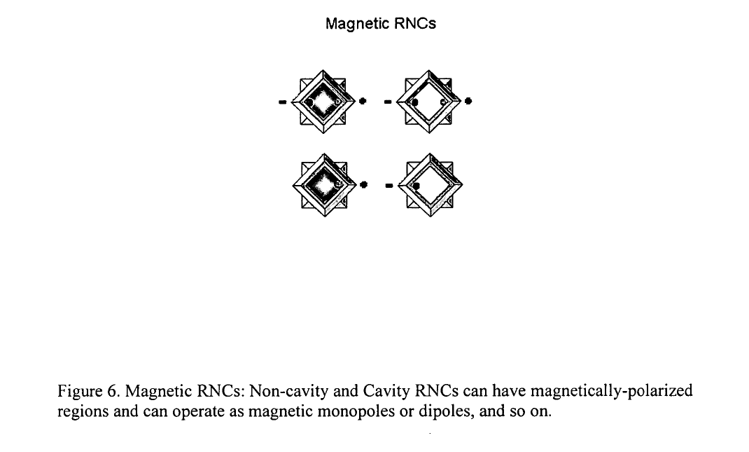

RNCs or other targets can be engineered to fit together like pieces of a jigsaw puzzle. They can also be designed as magnetic monopoles (FIG. 6 Magnetic RNCs). These RNCs/targets can be used to transport partially assembled molecules or drugs into the bloodstream and cells. Once inside the blood stream, across the blood brain barrier, or within cells, the RNCs can be used to reassemble the parent molecule or drug using RA or other technique.

RNCs or other targets with electrically-conductive properties can be absorbed by dendrites and incorporated within neurons. As such, RA and RNCs or other targets can improve neural conduction.

RA and RNCs or other targets can be used to improve resolution, contrast, and signal-to-noise ratios for imaging technologies, including but not limited to ultrasound, phonon (THz), infrared, magnetic resonance, x-rays, EBT, and CT.

Electrically-conductive and/or magnetic RNCs or other targets that are absorbed within neurons can enable improved imaging of neurons.

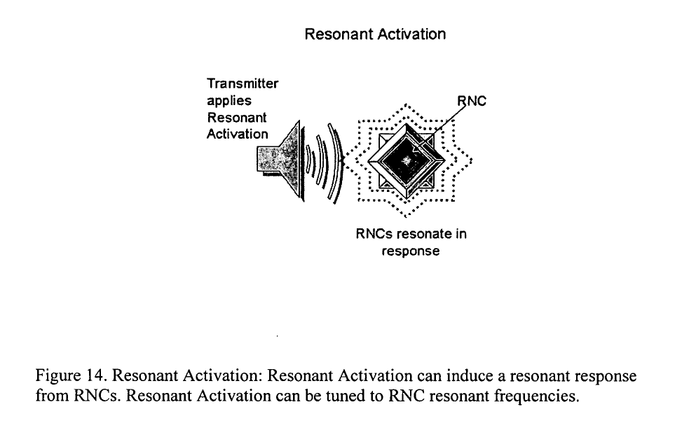

RNCs can have a molecular hinge that allows them to have an open or closed configuration. In the open state, the RNCs can be used to attract or randomly capture intra- and intra-cellular contents. When resonant activation is applied, the molecular hinge closes the RNC to trap the contents. The RNCs can then be harvested and reopened by ResonantActivation to release the contents (FIG. 14 RNC Nano-traps).

RA and RNCs or other targets designed as nano-traps can capture intracellular and intercellular contents. The RNCs are closed by the application of a trap-triggering RA. The RNCs/targets can then be excreted or otherwise filtered out of the host. They can then be opened using a trap-opening RA. The released contents can then be analyzed.

RA and RNCs or other targets can be used for anti-angiogenesis therapies to physically block capillaries at the sites of tumors, thereby starving the tumor and killing it.

RA and RNCs or other targets can be used to block migration of metastatic cells from the tumor site. One possible mechanism for this is interfering with the circulatory and/or lymphatic passage of the metastatic cells.

RNCs or other targets can be used as synthetic antibodies, thereby attaching to target cells and/or chemical compounds (such as antigens) in vivo. These RNCs/targets can then be phagocytized or eliminated by the host This application can enhance the immune system and immune function of the host. Some, but not all, of the cells that can be targeted by RNCs are microbes and cancer cells, including those in blood and lymph. The targets can be activated by RA.

### EXAMPLE OF AN IN-VIVO PROTOCOL

The following is a sample method/protocol for in vivo application of RA using Resonant Nano Crystals.

Basic Method/Protocol:

1. RNCs are designed and fabricated.
2. RNCs are administered to patients and animal hosts in a variety of ways. Some, but not all possibilities include oral, intravenous, htra-arterial, intra-lymphatic, intra-CSF, direct surface application, and direct vaccination.
3. Once administered, RNCs travel to the target tissues and are incorporated.
4. RA imaging is performed on the patient using the resonant frequencies of the RNC to confirm the level and targeting of RNC incorporation.
5. Resonant pulses/waves via RA are applied at the proper frequency, strength, and duration to cause desired effect on RNCs and tissues.
6. The RNCs are eliminated by the body via natural body processes, including, but not limited to kidneys, liver, and phagocytosis.
   Detailed Method/Protocol:
   Phase 1: Design and Fabrication
1. Design Resonant Nano Crystal
   a. Choose Cavity or Non-Cavity RNC
      i. Cavity RNC
         1. Single- or Multi-Chamber Cavity
         2. Cavity Size
         3. Cavity Shape
         4. Harmonic Bridges or None
      ii. Non-Cavity RNC
   b. Choose Payload or No Payload
      i. For Cavity RNC
         1. Payload
            a. Payload
            i. Choose Payload
            ii. Loose Payload?
            iii. Payload Attached to Cavity Wall?
            b. Nested RNC
         2. No Payload
      ii. For Non-Cavity RNC
         1. Payload
            a. Embedded Payload
            i. Choose Payload
         2. No Payload
   c. Design RNC Composition
      i. Si, SiO2
      ii. Other
   d. Design Size
   e. Design External Shape
   f. Design Fracture Regions
      i. Multiple Fragments
      ii. Simple Cleave
      iii. None
   g. Design Resonance
      i. Resonance Response Frequencies
      ii. Fracture Threshold
      iii. Resonance Frequency for activating payload (in cavity or on surface)
2. Design or Choose Targeting Materials
   a. Surface Coating
      i. Metabolic/Functional Attractants
      ii. Inactive/Active payload
      iii. Protective Resonant Shell
      iv. Other
   b. No Surface Coating
   c. Attached Compounds
      i. Ligands
      ii. Other
   d. No Attached Compounds
   e. Surface Structures
   f. No Surface Structures
3. Fabricate RNC and Integrate Payload and Targeting Method
   Phase 2: Administer and Diagnose
   1. Choose mechanism of administration
      a. Intravenous, Vaccination, Intralymphatic, Transdermal,
   2. Administer RNCs to Patient
   3. Scan/Image Patient Using RA to Confirm RNC Absorption/lncorporation
      a. Impose RA to Activate RNC Resonance
      b. Measure/Record Resonance using Imaging
      c. Confirm targeting and concentration at target tissue
      d. Confirm minimal involvement of non-target tissue
   4. Diagnose
      a. Confirm Diagnoses and Extent in Real-Time
         Phase 3: Perform Treatment and Monitor
   1. Apply RA at sufficient frequency, amplitude, and duration to:
      a. Fracture RNC and deliver payload, and/or
      b. Fracture RNC and mechanically damage target tissue, and/or
      c. Resonate RNC and affect target tissues through heat, electrical discharge, vibration, or other means.
   2. Monitor/Scan/Image Using RA Patient to Confirm Treatment Completeness and Results
      a. Impose RA and look for presence of RNCS. Insignificant or zero resonance can indicate RNCs were fractured and can be eliminated. Initial treatment is complete.
         Phase 4: Follow-Up
   1. Repeat Phases 2 and 3 until desired treatment effect achieved.
      Example In Vitro Protocol
   1. RNCs can be administered to cell cultures to target and eliminate unwanted biological matter, such as malignant cells, proteins or other molecules, and microbes.
   2. RA is applied at an appropriate frequency, strength, and duration to cause desired effect on RNCs and cell culture.
   3. The RNCs are filtered out by standard centrifuge techniques or other mechanisms.
      Example Wound Closure Method
   1. Administering magnetic targets (compounds and/or devices or structures, such as magnetic RNCs) to wound/incision.
   2. Allowing magnetic targets to incorporate into cells of wound Ancision margins.
   3. Applying magnetic stimulus/stimuli to induce magnetic convergence and close wound/incision.
   4. After wound is healed, (optionally) fracturing RNCs via resonant activation.
      Example Incision Separation/Closure Method
   1. Creating an incision and administering magnetic targets (compounds and/or devices or structures, such as magnetic RNCs) to wound Ancision.
   2. Allowing magnetic targets to incorporate into cells of wound Ancision margins.
   3. Applying magnetic stimulus/stimuli to induce magnetic divergence and open incision.
   4. After incision is healed, (optionally) fracturing RNCs via resonant activation.

### ALTERNATIVE EMBODIMENTS

RA and RNCs or other targets can be used to replace and/or supplement X-ray diagnostic techniques for dentistry. It can also be used to treat dental conditions. For example, RA and RNCs/targets can be used to affect a response from targeted chemical compounds and/or devices or structures to image/reveal and/or remove/destroy dental tartar and plaque and/or the bacteria that produce these substances.

Oxygenation Applications

RNCs can be used to carry oxygen molecules directly into target cells, including blood cells and muscle tissues. Once in the cells, they can be later activated by an external stimulus or stimuli for an oxygen boost to the host.

Botanical Applications

RNCs can be used to administer drugs and other chemicals, including fertilizers directly to plant cells. RNCs can be absorbed by root systems, injected into the plant phloem, or administered directly to plant cells via stomata used for respiration.

Physics of Resonating Nanocrystals

Resonant nanostructures, as exemplified by resonant nanocrystals, resonate based on well-studied principles of physics. All materials, solid and non-solid, have inherent resonant properties. Any structure can resonate when a driving force (stimulus) is applied to it. The structure exhibits the highest degree of resonance (highest resonant amplitude) when the driving force is at or near the resonance frequency of the structure. The degree of resonance is generally equated with the quality factor (Q-factor) of the structure. The Q-factor (Q) is a measure of rate at which a resonating structure dissipates (damps) its energy. The higher the Q-factor, the lower rate of energy dissipation. When a structure is driven at resonance, the amplitude of its steady-state vibrations is proportional to Q. Therefore, the higher the Q-factor, the greater is the amplitude of the resonant response. It is well established that semiconductor microdots and nanodots used in quantum optics and photonics have very high Q-factors. By extension, resonant nanocrystals are expected to have similarly high Q-factors and be highly resonant in response to a suitable driving force. In cavitated RNCs, the interior surfaces of the cavity reflect the applied driving force waves. When the frequency of the wave is resonant with that of the cavity (known as the standing wave), it is reflected within the cavity with low dissipation. As more driving force energy enters the cavity, it adds to and reinforces the standing wave, increasing the wave amplitude and the resulting resonant response of the RNC.

RNC Manufacturing Process

Resonant nanocrystals can be manufactured using established semiconductor fabrication techniques. They can be manufactured with a highdegree of consistency and with a high yield per manufacturing run. Techniques used in the fabrication can include, but are not limited to, molecular beam epitaxy (MBE) and multi-step CMOS fabrication using short-wavelength lithography such UV photolithography, X-ray lithography, and/or electron beam lithography. It is well established that these techniques can be used to create three-dimensional structures on the micro and nano scales, in particular the fabrication of quantum wells and quantum dots in VLSI IC design. However, RNCs have unique properties that are engineered duringthe fabrication process, including for example, engineering their geometry, surface characteristics, size and weight, cavity size and shape, resonance properties, and fracturing regions. Further, during the fabrication process payloads (atomic, molecular, and/or biobgical) and/or other coatings are added to the RNCs.

### EQUIVALENTS OF THE INVENTION

While particular embodiments of the invention and variations thereof have been described in detail, other modifications of resonating nanostructures, such as the exemplary resonant nanocrystals, and methods of using the resonance activation of nanostructures will be apparent to those of skill in the art. Accordingly, it should be understood that various applications, modifications, and substitutions may be made of equivalents Without departing from the spirit of the invention or the scope of the claims. Various terms have been used in the description to convey an understanding of the invention; it will be understood that the meaning of these various terms extends to common linguistic or grammatical variations or forms thereof. It will also be understood that when terminology referring, for example to physical equipment, hardware, or software has used trade names or common names, that these names are provided as contemporary examples, and the invention is not limited by such literal scope. Terminology that is introduced at a later date that may be reasonably understood as a derivative of a contemporary term or designating of a subset of objects embraced by a contemporary term will be understood as having been described by the now contemporary terminology. Further, it should be understood that the invention is not limited to the embodiments that have been set forth for purposes of exemplification, but is to be defined only by a fair reading of claims that will be appended to the non-provisional patent application, including the full range of equivalency to which each element thereof is entitled.

What is claimed is:

1. A resonant nanostructure comprising at least one nanoscaled vesicle measuring from about 1 nanometer to about 1000 nanometers in at least one dimension, the nanoscaled vesicle having resonant properties and capable of generating a resonant response to an external stimulus.

2. The resonant nanostructure of claim 1, wherein the nanoscaled vesicle is crystalline in nature.

3. The resonant nanostructure of claim 1, wherein the nanoscaled vesicle is devoid of a cavity.

4. The resonant nanostructure of claim 1, wherein the nanoscaled vesicle includes a cavity configured to permit transport of a payload or other resonant structures therein.

5. The resonant nanostructure of claim 4, wherein the nanoscaled vesicle is configured for time release of the payload.

6. The resonant nanostructure of claim 4, wherein the resonant response includes mechanical fracturing, the mechanical fracturing resulting in the release or exposure of the payload.

7. The resonant nanostructure of claim 4, wherein the resonant response includes a transfer of energy that is absorbed by the payload, the payload being an inactive compound, such that absorption of energy by the inactive payload causes transformation of the inactive payload into an active payload.

8. The resonant nanostructure of claim 1, wherein the resonant response occurs within one picosecond to one hour or longer following the stimulus.

9. The resonant nanostructure of claim 1, wherein the response is controlled by one of a time course of the stimulus, strength of the stimulus, local environment, resonant potential of the nanoscaled structure, or a combination thereof.

10. The resonant nanostructure of claim 1, wherein the resonant response includes mechanical fracturing.

11. The resonant nanostructure of claim 1, wherein the resonant response includes remaining intact.

12. The resonant nanostructure of claim 1, wherein the external stimulus includes one of an electromagnetic stimulus or an acoustic stimulus.

13. The resonant nanostructure of claim 1, further comprising compounds attached to the nanoscaled vesicle so as to target other compounds.

14. The resonant nanostructure of claim 1, further comprising fracture regions that can determine one of an extent or force of a fracturing response, or a combination thereof.

15. The resonant nanostructure of claim 1, further comprising a harmonic region that can affect the response, such effects including one of an enhancement of the resonating response, a tuning of the resonating response, or a combination thereof.

16. The resonant nanostructure of claim 1, further comprising an electrically-charged region.

17. The resonant nanostructure of claim 1, further comprising one of a hydrophobic region, a hydrophilic region, an amphipathic region, or a combination thereof.

18. The resonant nanostructure of claim 1, further comprising a coating about the nanoscaled structure that can attract one of a cell, a chemical compound, another resonant structure, or a combination thereof.

19. The resonant nanostructure of claim 1, further comprising a coating about the nanoscaled structure that can shield underlying structures from the environment.

20. The resonant nanostructure of claim 1, further comprising a coating about the nanoscaled structure that can resonate in response to one of an electromagnetic stimulus, an acoustic stimulus, or a combination thereof.

21. The resonant nanostructure of claim 1, further comprising a coating about the nanoscaled structure that can fracture in response to one of an electromagnetic stimulus, an acoustic stimulus, or a combination thereof.

22. The resonant nanostructure of claim 1, wherein the nanoscaled structure can be configured to attach to a cell surface, get incorporated within a cell to identify molecules or biological structures therein, or a combination thereof.

23. The resonant nanostructure of claim 1, wherein the nanoscaled structure can be configured to trap a chemical compound, cell organelle, or other structure.

24. The resonant nanostructure of claim 1, wherein the nanoscaled structure can be configured to assemble chemical compounds from attached chemical sub-compounds.

25. The resonant nanostructure of claim 1, wherein the nanoscaled structure can be configured to attach to a cell membrane and deliver a payload to the cell.

26. The resonant nanostructure of claim 1, wherein the nanoscaled structure includes a magnetically-polarized region capable of attracting one of a structure, a chemical compound, or a combination thereof via an electromagnetic force.

27. A method of inducing a resonant response, the method comprising:
providing a structure having resonant properties and capable of generating a resonant response;
directing the structure to a targeted area; and
applying a stimulus to the targeted area, so as to induce a resonant response from the structure.

28. The method of claim 27, wherein, in the step of providing, the structure includes one of a nano-scale device, vesicle, or particle, a micro-scale device, vesicle, or particle, a chemical compound, a molecule, an atom, or a combination thereof.

29. The method of claim 27, wherein, in the step of providing, the structure measures from about 1 nanometer to about 1000 nanometers in at least one dimension.

30. The method of claim 27, wherein, in the step of directing, targeted area is located in a living system.

31. The method of claim 30, wherein the step of applying includes allowing the stimulus applied to the targeted area to penetrate through living tissue.

32. The method of claim 27, wherein the step of applying includes allowing the targeted area to be altered during the resonant response.

33. The method of claim 27, wherein, in the step of applying, the stimulus includes one of an electromagnetic force, an acoustic force, or a combination thereof.

34. The method of claim 33, wherein, in the step of applying, the electromagnetic stimulus includes one of a microwave, an infrared wave, magnetic resonance imaging, nuclear magnetic resonance, computed tomography, electron beam tomography, single photon emission computed tomography, positron emission tomography, an X-Ray, T-ray (TeraHertz) phonon imaging, or a combination thereof.

35. The method of claim 33, wherein, in the step of applying, the acoustic stimulus includes one of an ultrasound, an infrasound, or a combination thereof.

36. The method of claim 27, wherein, in the step of applying, the stimulus occurs on a time course and is of a predetermined strength, the targeted area is in a local environment and has a resonant potential, and wherein the resonant response is controlled by one of the time course of the stimulus, the strength of the stimulus, the local environment, a resonant potential of the targeted area, or a combination thereof.

37. The method of claim 27, wherein, in the step of applying, the resonant response has a spatial scope with respect to the resonant target, and wherein the stimulus occurs on a time course and is of a predetermined strength, the target area is in a local environment and has a resonant potential, and wherein the spatial scope of the response is controlled by one of the time course of the stimulus, the strength of the stimulus, the local environment, a resonant potential of the targeted area, or a combination thereof.

38. The method of claim 27, wherein, in the step of applying, the resonant response has a magnitude, and wherein the stimulus occurs on a time course and is of a predetermined strength, the targeted area is in a local environment and has a resonant potential, and wherein the magnitude of the response is controlled by one of the time course of the stimulus, the strength of the stimulus, the local environment, a resonant potential of the targeted area, or a combination thereof.

39. The method of claim 27, wherein, in the step of applying, the resonant response occurs from about one picosecond to about one hour, or longer following the stimulus, and can be controlled by one of a time course of the stimulus, a strength of the stimulus, a local environment, a resonant potential of the targeted area, or a combination thereof.

40. The method of claim 27, wherein the step of applying includes utilizing the resonant response for medical imaging, so as to improve quality of the imaging.

41. The method of claim 40, wherein, in the step of utilizing, an improvement to the quality of the imaging results from one of a reduction in signal to noise ratio, an enhancement of spatial resolution, an enhancement of temporal resolution, an enhancement of contrast, a reduction of artifacts, or a combination thereof.

42. The method of claim 27, wherein the step of applying includes utilizing the resonant response to diagnosis of diseases.

43. The method of claim 27, wherein the step of applying includes utilizing the resonant response for staging of disease.

44. The method of claim 27, wherein the step of applying includes utilizing the resonant response for treatment of diseases.

45. The method of claim 27, wherein the step of applying includes utilizing the resonant response to elucidate biological function at one of system level, organ level, tissue level, cellular level, intracellular level, or a combination thereof.

46. The method of claim 27, wherein the step of applying includes utilizing the resonant response for real time confirmation of an occurrence of the resonant response.

47. The method of claim 27, wherein the step of applying includes utilizing the resonant response for real time confirmation of an occurrence of a consequence that follows from a resonant response.

48. The method of claim 27, wherein the step of applying includes utilizing the resonant response to generate a biological response that can be measured in real time.

49. The method of claim 48, wherein, in the step of utilizing, the biological response is a related to neurological function.

50. The method of claim 27, wherein the step of applying includes utilizing the resonant response to attract chemical compounds to a vicinity of the response.

51. The method of claim 50, wherein the step of utilizing includes permitting the attraction of chemical compounds to occur through one of a magnetic interaction, an ionic interaction, or a combination thereof.

52. The method of claim 50, wherein the step of utilizing includes permitting the attraction of chemical compounds to enable self assembly of larger compounds from attracted chemical compounds.

53. The method of claim 27, wherein the step of applying includes utilizing the resonant response to disassemble compounds in the vicinity of the response.

54. The method of claim 27, wherein the step of applying includes utilizing the resonant response to separate compounds in the vicinity of the response through one of a magnetic interaction, an ionic interaction, other interaction, or a combination thereof.

55. The method of claim 27, wherein the step of applying includes utilizing the resonant response to induce a change in the structure, provided with a payload, so as to promote a time-delayed release of the payload.
